(19) United States
(12) Patent Application Publication
(10) Pub. No.: US 2020/0261858 A1
(43) Pub. Date: Aug. 20, 2020

(54) PERMEABLE GRAPHENE AND PERMEABLE GRAPHENE MEMBRANES

(71) Applicants: Commonwealth Scientific and Industrial Research Organisation, Acton, ACT (AU); Queensland University of Technology, Queensland (AU)

(72) Inventors: Dong Han Seo, Acton, ACT (AU); Shafique Pineda, Acton, ACT (AU); Adrian Murdock, Acton, ACT (AU); Zhao Jun Han, Acton, ACT (AU); Kostyantyn Ostrikov, Acton, ACT (AU); Ming Xie, Acton, ACT (AU); Timothy Van der Laan, Acton, ACT (AU)

(21) Appl. No.: 16/491,650

(22) PCT Filed: Mar. 6, 2018
(86) PCT No.: PCT/AU2018/050204

§ 371 Date: Sep. 6, 2019

(30) Foreign Application Priority Data
Mar. 6, 2017 (AU) 2017900765
Dec. 20, 2017 (AU) 2017905092

(51) Int. Cl. B01D 67/00; B01D 69/10; B01D 71/02; C02F 1/44; B01D 69/02; C23C 16/448; C23C 16/01; C23C 16/26; C23C 16/56; C01B 32/186

(52) U.S. Cl. CPC B01D 67/0072; B01D 69/10; B01D 71/021; C02F 1/447; B01D 69/02; C02F 2101/301; C23C 16/01; C23C 16/26; C23C 16/56; C01B 32/186; C23C 16/448

(57) ABSTRACT

Continuous permeable graphene films having 2 or more layers of graphene and wherein nanochannels or nanopores extend through said film. Each nanochannel is comprised of a fluidly connected series of gaps between edge mismatches of adjacent graphene grains within said 2 or more layer adjacent sheets, said nanochannels providing a fluid passage from one face of the permeable graphene film to the other. Also, membranes including a permeable support membrane overlaid by a continuous permeable graphene film and processes for the preparation of said membranes. Also the use of said membranes in water purification and desalination, for example.

### FIELD OF THE INVENTION

The invention relates to permeable graphene films, permeable graphene membranes, methods for the production of said films and membranes and the use thereof, particularly in relation to water filtration. In particular, the invention relates to permeable nanoporous and nanochannel graphene. The permeable graphene films can be prepared by single-step process involving thermal methods in ambient air followed by cooling under vacuum without using expensive feedstock gases and it is further possible to use renewable biomass as a carbon source. The permeable graphene membranes comprise a permeable support membrane overlaid by a continuous permeable graphene film of the invention.

### BACKGROUND ART

Graphene exhibits unique electronic, optical, chemical and mechanical properties. Because of its extremely high electron mobility (electrons move through graphene about 100 times faster than silicon), very low absorption in the visible spectrum and relative flexibility and elasticity (compared to inorganics such as indium tin oxide), supported horizontal graphene as an active functional material has been revolutionising many fields. For instance, graphene is potentially useful for flexible, transparent, and wearable electronics, in energy storage devices (e.g., fuel cells, supercapacitors, photovoltaics, lithium-ion batteries, etc), in devices for diagnostics and therapeutics (e.g., biosensors, bioelectronics, drug delivery), in water purification (e.g., point-of-use filtration membranes) and in catalysis (e.g., to promote hydrogen evolution reactions). Control of defect content, microstructure, and surface chemical properties in the graphene will be critical to maximising the potential of graphene in these applications.

Graphene can be produced by a variety of methods. The mass production of graphene, which would be essential for widespread commercial use, has to date been targeted by a small number of general processes, most notably:
mechanical grinding of graphite and dispersion in solution followed by self-assembly.
thermal graphitisation of SiC.
chemical vapour deposition (CVD) onto metal substrates.

Of these three methods, CVD onto metal substrates is the most promising, as it produces graphene films of sufficiently high quality to allow the potential of graphene to be more fully realised. CVD also allows roll-to-roll graphene synthesis.

The quality of the graphene produced is critical to its ability to function as a high performance material. High quality graphene possesses a minimal number of defects from the ideal perfectly regular sp² carbon film, and is also very thin, that is, the bulk material produced contains as few carbon atomic layers as possible.

The quality of graphene can be expressed quantitatively in terms of its electronic and optical performance. A low number of defects leads to a very low film resistance, which can typically be around 200 Ω/sq. Defects in the graphene can diminish in-plane charge carrier transport which compromises the promising properties required for efficient field-emission, ultra-fast sensing and nano-electronics based devices.

Very thin films, for instance those having only one, two or three carbon atomic layers are highly transparent and have a transmittance of up to 97% which is useful for optical displays.

Thicker films and graphene in other forms (such as grains and coatings) can be useful in other circumstances, such as catalysis and filtration. An ability to control the thickness of graphene grown is highly desirable.

However, CVD onto metal substrates has some inherent limitations. The CVD apparatus itself is complex and expensive. CVD consumes very large amounts of power and like other thermal methods currently used, requires a low-pressure vacuum environment. This means that there are significant capital and ongoing operating costs associated with CVD. Also, the cost of vacuum equipment increases exponentially with the size of the vacuum chamber which limits the manufacturers' ability to scale up the process in a cost-effective manner.

CVD also requires the use of highly purified feedstock gases, which are expensive. The use of gases such as hydrogen for substrate passivation and methane and ethylene as carbon source gases also means that additional hazard protection also needs to be put in place.

CVD also requires relatively long time frames, of the order of hours, for the growth, annealing and cooling steps to take place. This inherent requirement means that CVD is not readily amenable to the rapid mass production of affordable graphene.

The search for new methods of graphene is a very active area of endeavour and many researchers are investigating synthetic routes to high quality graphene that are safe, inexpensive and amenable to scale up.

The present Applicant has described a method of graphene synthesis in their earlier patent application PCT/AU2016/050738 which enables inexpensive production of high quality graphene in large quantities.

Modifications to the morphology of graphene are likely to give rise to additional uses. One particularly desirable modification would be the production of porous graphene. It has been envisaged that graphene sheets having pores passing from one side of the graphene film to the other would have significant potential for use in air purification (particulate, volatile organic compound filtration) water purification (coal seam gas waste water treatment, mine waste water treatment, heavy metal removal); liquid-liquid separation, such as osmosis, reverse osmosis, desalination, membrane distillation, solvent extraction and solvent separation; air purification, catalysis; energy storage devices; medical devices (bioelectronics, drug delivery) and so on.

In order to be useful, a porous graphene needs to be produced in an economical, reproducible manner. Thus far, obtaining porous graphene of a high quality, with a useful pore structure and at a sufficient scale to be commercially useful, has proved to be elusive.

Graphene films or layers having passages from one side to the other can arise accidentally as a result of intrinsic defects, for example those generated (i) during the graphene transfer process [Suk, J. W. et al. ACS Nano 2011, 5, 6916-6924.], or (ii) from the CVD growth of graphene on Cu [Li, X et al. Science 2009, 324, 1312-1314.]. These multistep processes involve the use of purified gases, extensive vacuum processing and prolonged high temperature annealing. These defects are sporadic and isolated and may require additional polymer chemistry to seal the accompanying larger defect sites (i.e., cracks and tears). [Jain, T.; et al. Nat Nano 2015, 10, 1053-1057; O'Hern, S. C. et al. Nano Letters 2015, 15, 3254-3260; O'Hern, et al. ACS Nano 2012, 6, 10130-10138.]

A number of techniques have been used in an attempt to create pores in graphene.

One approach is ion bombardment. This approach is limited to very small scale work and is expensive process requiring ultra-high vacuum conditions. [WO2014152407; US20130270188; U.S. Pat. No. 8,894,796; O'Hern, S. C.; et al. Nano Letters 2014, 14, 1234-1241; Surwade, S. P. et al. Nat Nano 2015, 10, 459-464; Celebi, K. et al. Science 2014, 344, 289-292; Russo, C. J.; Golovchenko, J. A., A. Proceedings of the National Academy of Sciences 2012, 109, 5953-5957.]

Ultraviolet etching has also been used but the density of pores formed is very low, and there is a wide distribution in the pore sizes. [Koenig, S. P. et al. Nat Nano 2012, 7, 728-732; Liu, L. et al. Nano Letters 2008, 8, 1965-1970; Huh, S. et al. ACS Nano 2011, 5, 9799-9806.]

Block copolymer and nanosphere (template) lithography has also been used. This process is very complex and multi-staged and requires additional lithography techniques to carefully remove template residues without further damaging the graphene. [US 20140154464; Safron, N. S. et al. Advanced Materials 2012, 24, 1041-1045; Liang, X. et al. Nano Letters 2010, 10, 2454-2460; Jackson, E. A.; Hillmyer, M. A., ACS Nano 2010, 4, 3548-3553.]

High voltage electrical pulses have also been used although again these are limited to small scale production and require complex setups. [Rollings, R. C. et al., Nature Communications 2016, 7, 11408; Kuan, A. T. et al. Applied Physics Letters 2015, 106, 203109.]

Electron beam lithography has also been used. In addition to being a small-scale process, the high-energy electron beam used generates undesired defects such as induced amorphization and the deposition of carbon atoms on graphene. [US 20130309776; Garaj, S. et al. Nature 2010, 467, 190-193; Merchant, C. A.; et al. Nano Letters 2010, 10, 2915-2921; Garaj, S. et al. Proceedings of the National Academy of Sciences 2013, 110, 12192-12196; Schneider, G. F. et al. Nature Communications 2013, 4, 2619; Fischbein, M. D., Drndić, M., Applied Physics Letters 2008, 93, 113107.]

The current techniques used to prepare nanoporous graphene are all carried out as additional post-processing steps following the CVD synthesis of graphene films, and therefore include all the disadvantages inherent therein, such as the need to use purified gases, extensive vacuum processing, and prolonged high-temperature annealing. The techniques used to date also suffer from multiple drawbacks such as lack of scaleabily to industrially useful size films, high cost, high complexity and lack of consistency and control in the subsequent film.

Graphene is potentially useful as an ultrathin membrane that has atomically defined nanochannels with diameters approaching those of hydrated ions. A pristine single-layer of graphene is impermeable to standard gases (e.g., helium)′. The introduction of selective defects throughout the graphene lattice can potentially enable permeance of water molecules. As described above recent advances in post-synthesis reactive processing of CVD graphene have produced atomically-thin permeable films potentially suitable for water purification.^{2, 3, 4} However, these techniques involve a series of highly-controlled, resource-intensive, and complex procedures which are difficult to uniformly implement in high density and large scales. Thus, the capability of CVD graphene films for water purification and desalination remains restricted to small-scale demonstrations (μm scale).² Moreover, while CVD synthesis offers good control over the growth of graphene films, it remains an expensive process due to the necessity of compressed gases and extensive vacuum operation. Furthermore, often, hydrophobic nature of CVD graphene creates additional hurdles for utilization in water purification membrane. Consequently, these technical challenges impede the commercial viability of CVD graphene films for water purification.⁵

Graphene has potential as a water purification material. Concerns over clean water supply, and environmental impact of industrial waste water, makes water treatment a world-wide issue requiring a simple and effective solution.

An important technique used for water purification is membrane filtration and a particularly important subset of membrane filtration is membrane distillation, otherwise known as MD. Membrane distillation complements industrial reverse osmosis processes. Membrane distillation achieves high rejection over a range of salt concentrations whilst maintaining flux, using differential temperature as opposed to pressure across the membrane. MD has a few notable drawbacks, namely the energy intensive process of heating and maintaining the feed water temperature and the inability of MD membrane to handle diverse contaminant mixtures.^{7, 9} Recently, the problem of energy intensive process has been solved by implementing carbon nanotube/polymer composite as an effective pathway to locally generate the heat at the membrane interface.¹⁰ However, some key problems with MD and similar membrane filtration processes remain unsolved. First when common chemical or oil-based contaminants are introduced during the MD filtration process, membranes exhibit significant fouling behaviour which rapidly degrades the membrane performance and leads to irreversible degradation of the membrane.^{11, 12} Such fouling problem during MD operation reduces water recovery, fails to maintain contaminant rejection, increases the demand for harsh chemical cleaning, and rapidly diminishes the lifetime of the membrane. Secondly, the inability of conventional MD membranes to insulate the heat conduction across the membrane often leads to low water vapour flux with degradation of performance over a long-period of operation which remains as another significant challenge.¹³

Thirdly, it is known that currently no membrane maintains filtration performance under harsh (high salt, acid and/or base concentrations) conditions

Such limitations of conventional membranes emphasise the need for new materials to realize anti-fouling membranes capable of addressing these challenges. Improved MD membranes have been fabricated by several techniques such as phase inversion and electrospinning of polymers. However, most of these methods have been unable to achieve anti-fouling membranes which demonstrated high water vapour flux and long-term stability during MD operation under diverse mixtures of membrane damaging contaminants.^{14, 15}

Despite the small intrinsic pores which restricts water vapour passage, CVD graphene films possess numerous physiochemical properties which are valuable for MD application. These include its good mechanical strength, thermal and chemical stability, hydrophobicity, atomically thin thickness, and high out-of-plane thermal resistance (low thermal conductivity in Z direction).^{16, 17} Recently, enhancements in the performance of water purification processes have been demonstrated with the incorporation of graphene flakes in the membranes.¹⁸ However, until now, the extensive promises and potential of 2D graphene films for water purification have not been realized.

It is an object of the present invention to overcome or ameliorate at least one of the disadvantages of the prior art, or to provide a useful alternative.

Any discussion of the prior art throughout the specification should in no way be considered as an admission that such prior art is widely known or forms part of common general knowledge in the field.

Unless the context clearly requires otherwise, throughout the description and the claims, the words “comprise”, “comprising”, and the like are to be construed in an inclusive sense as opposed to an exclusive or exhaustive sense; that is to say, in the sense of “including, but not limited to”.

The present application

### SUMMARY

In a broad aspect, the invention provides a continuous permeable graphene film having nanochannels or nanopores providing a fluid passage from one face of the permeable graphene film to the other. The film may contain for example 1-40 layers of graphene

In another broad aspect, the invention provides a continuous permeable graphene film comprising 2 or more layers of graphene and nanochannels or nanopores providing a fluid passage from one face of the permeable graphene film to the other. The film may contain for example 2-40 layers of graphene.

More preferably, the invention provides a continuous permeable graphene film described in the broad aspect above comprising 2 or more layers of graphene forming nanochannels wherein each nanochannel being comprised of a fluidly connected series of gaps between edge mismatches of adjacent graphene grains within said 2 or more layer adjacent sheets, said nanochannels providing a fluid passage from one face of the permeable graphene film to the other.

According to a first aspect the invention provides a continuous permeable graphene film comprising 2 or more layers of graphene and wherein nanochannels extend through said film, each nanochannel being comprised of a fluidly connected series of gaps between edge mismatches of adjacent graphene grains within said 2 or more layer adjacent sheets, said nanochannels providing a fluid passage from one face of the permeable graphene film to the other.

The gaps are located at the junction of grain boundaries in the graphene film.

The 2 or more layers may comprise preferably 2-40 layers of graphene or more preferably 2-10 layers of graphene.

As used herein “continuous permeable graphene film” means a film of graphene comprising pores or nanochannels that have openings that extend from one side of the film to another (that is said pores or nanochannels provide a fluid passage through the graphene film z-axis). The graphene films allow the permeation of gas with any suitable molecular size or any fluid or substance flow across the film at positions where the pores or channels exist. In the case of porous graphene, the continuous opening may be in one or more sheets, for example, between 1-5 graphene sheets. For nanochannel graphene, the opening is in the form of an interconnected continuous channel that spans across 2-10 or as much as 2-40 graphene sheets. The channel is created by mismatched stacking of the graphene sheets.

Preferably the gaps are located near the grain boundaries of the graphene film. It is also preferred that the nanochannel graphene film has a functional pore size of 0.37-3 nm

According to a second aspect the invention provides a permeable membrane comprising a permeable support membrane overlaid by a continuous permeable graphene film, said continuous permeable graphene film having a plurality of nanochannels extending therethrough.

Preferably, the continuous permeable graphene film comprises 2 or more layers of graphene and wherein nanochannels extend through said continuous permeable graphene film, each nanochannel comprising a fluidly connected series of gaps between edge mismatches of adjacent graphene grains within said 2 or more layer adjacent sheets, said nanochannels providing a fluid passage from one face of the permeable graphene film to the other.

That is, the invention provides a permeable membrane comprising a permeable support membrane overlaid by a continuous permeable graphene film of the first aspect

The 2 or more layers of graphene may comprise preferably 2-40 layers of graphene or more preferably 2-10 layers of graphene.

In some embodiments, the continuous permeable graphene film has a thickness of 0.7 to 3.7 nm, for instance, the continuous permeable graphene film has a thickness of 1.7 nm.

In some embodiments, the continuous permeable graphene film has functional pore size in the range of 0.34-3.0 nm, preferably 0.34 nm.

Preferably, the permeable membrane is a two component membrane wherein the permeable support membrane and the graphene film are adjacent to each other or attached to each other.

In an alternative embodiment, the invention provides a permeable membrane comprising a permeable support membrane sandwiched between two continuous permeable graphene films, each continuous permeable graphene film having a plurality of nanochannels or nanopores extending therethrough.

In yet a further alternative embodiment, the membrane may also be a composite membrane wherein the graphene film is incorporated into the permeable support membrane.

Preferably, the permeable support membrane is a porous polymeric membrane, for instance, the permeable support membrane is a porous polymeric membrane selected from the group consisting of PTFE (polytetrafluoroethylene), PVDF (polyvinylidene fluoride), polyethylene and polysulfone. However, any porous membrane or substrate that provides sufficient support for the graphene may be used.

The permeable support membrane may be a commercial porous polymeric MD (Membrane Distillation) membrane, for instance, the permeable support membrane is a commercial porous polymeric MD Membrane distillation membrane with a pore size of 0.1 μm or greater. The commercial porous polymeric MD Membrane distillation membrane may also have a thickness in the range of 100-200 μm10.

According to a third aspect the invention provides a method of preparing a deposited permeable continuous nanochannel graphene film comprising the steps of heating a metal substrate and an excess of carbon source in a sealed ambient environment to a temperature which produces carbon containing vapour from the carbon source such that the vapour comes into contact with the metal substrate, maintaining the temperature for a time sufficient to form a graphene lattice, cooling the sample at a retarded cooling rate under reduced pressure for a delay time, and then flash cooling the substrate under reduced pressure form a deposited permeable nanochannel graphene.

The method may further include the step of decoupling the permeable continuous nanochannel graphene film by standard procedures, such as those disclosed herein.

“Delay time” as used herein means the time allowed for the deposited graphene film to cool inside the sealed environment when the sealed environment is being cooled after formation of the graphene lattice.

Preferably, the ambient environment is air at atmospheric pressure or a vacuum. Importantly, unlike most methods in the art, the methods of the present invention are free from the use of a compressed gas or gases. Feedstock gases are not required. “Feedstock gases” as used herein includes any purified gas typically used in CVD processes for etching, blanketing or as a carbon source material and the term specifically includes, but is not limited to hydrogen gas, argon gas, nitrogen gas, methane gas, ethane gas, ethylene gas and acetylene gas.

The metal substrate may be a transition metal substrate, for preference the metal substrate is nickel or copper, most preferably nickel. The metal substrate can be in any suitable form, for example a flat foil or wire.

When the metal substrate is nickel the ambient environment is preferably air at atmospheric pressure. Preferably, the metal substrate is nickel of purity 99% and above, most preferably the metal substrate is polycrystalline nickel.

Alternatively, when the metal substrate is copper the ambient environment is preferably an evacuated chamber prior to sealing and heating.

The carbon source may advantageously be biomass or derived from biomass or purified biomass. The biomass or purified biomass may be for example a long chain triglyceride (fatty acid), such as soybean oil, or it may be a cellulosic material. Renewable biomass may be used. The carbon source may be in any form, such as liquid or solid form with liquid usually being considered advantageous.

The method is free from feedstock gases.

Preferably the step of heating employs a carbon rich, or carbon excess environment. It is preferred that during the step of heating the metal substrate and carbon source are both located in the one heating zone.

Preferably the sealed environment is an inert container, such as a quartz, glass or other dielectric heat resistant container. Most preferably the sealed environment is contained in a quartz tube.

‘Preferably the metal substrate and carbon source are heated to a temperature sufficient to form a graphene lattice in the range 650° C.-900° C., such as 800° C. or 900° C. The temperature sufficient to form a graphene lattice is maintained for a suitable time, ideally 0-3 minutes.

Preferably the heating is maintained in a heating zone and the flash cooling takes place in a cooling zone. Preferably, the graphene lattice is transferred from the heating zone to the cooling zone prior to flash cooling such that the delay time is zero or close to zero.

Preferably, the graphene lattice is flash cooled under reduced pressure by transferring the lattice from the heating zone to a cooling zone that is under vacuum.

Preferably flash cooling is at a rate of 25° C./minute −100° C./minute.

Preferably, the graphene lattice is transferred from the heating zone to the cooling zone such that the delay time is between 1 and 5 minutes.

Preferably, the retarded cooling rate takes place at a rate of from 5° C. to 10° C./minute, more preferably the retarded cooling rate takes place in the heating zone at a rate of from 10° C./minute.

The method may also further comprise the step of decoupling the deposited graphene film from the substrate to provide a graphene film. For instance, the method may further include the steps of removing or decoupling the continuous permeable graphene film from the metal substrate to produce a free continuous permeable graphene film.

A method of preparing a deposited permeable continuous nanochannel graphene film on a support membrane comprising preparing deposited permeable continuous nanochannel graphene film on a substrate in accordance with the third aspect, decoupling the film from the substrate to provide a free permeable continuous nanochannel graphene film and applying the free permeable continuous nanochannel graphene film to the support membrane.

The method may also further comprise the step of decoupling the deposited graphene film from the substrate to provide a graphene film. The permeable or nano-permeable graphene film may be decoupled by any conventional means.

The permeable or nano-permeable graphene film may be decoupled by any conventional means. For instance, it may be decoupled from the underlying metal substrate by dissolving the substrate in an acidic environment. In particular, a nickel substrate may advantageously be dissolved in H₂SO₄ or HCl or FeCl₃ or a copper substrate may be dissolved in any of the preceding or HNO₃.

The method may include the step of utilising a binder attached to the free permeable continuous nanochannel graphene film. The binder may be removed after the graphene film is applied to the support membrane, or it may be retained in use. That is, the final product comprises a deposited permeable continuous nanochannel graphene film, a binder layer, and a support membrane. The binder layer is permeable.

For example, the continuous permeable graphene film may, for instance, be removed by a PMMA assisted process to produce an intermediate PMMA bound graphene film which is removed from the underlying metal growth substrate. The PMMA bound graphene film is then applied to the support membrane. The PMMA layer may be removed, for example, by dissolution, or it may be retained in the final product.

As used herein, the term “decouple” “decouples”, “decoupling” and the like refer to the removal or lifting of a formed graphene from the underlying substrate to isolate a graphene film.

The invention provides a method of purifying a feed water contaminated with a contaminant comprising providing said feed water to a permeable graphene film according to the invention such that the feed water contacts the continuous permeable graphene film as a feed side, allowing water to pass through the permeable membrane to a filtrate side to provide a filtrate, and whereby the contaminant is retained on the feed water side.

The permeable graphene film is nanoporous graphene or more preferably, nanochannel graphene comprising 2 or more layers of graphene and wherein nanochannels extend through said film, each nanochannel being comprised of a fluidly connected series of gaps between edge mismatches of adjacent graphene grains within said 2 or more layer adjacent sheets, said nanochannels providing a fluid passage from one face of the permeable graphene film to the other. The nanoporous graphene film or nanochannel graphene film may be supported by a conventional membrane substrate.

According to a fifth aspect, the invention provides a method of purifying a feed water contaminated with a contaminant comprising providing said feed water to a permeable graphene film or permeable membrane according to the invention such that the feed water contacts the continuous permeable graphene film as a feed side, allowing water to pass through the permeable membrane to a filtrate side to provide a filtrate, and whereby the contaminant is retained on the feed water side.

Preferably, the process is membrane distillation and the feed water is provided to the permeable membrane at an elevated temperature relative to the filtrate.

In a more preferred embodiment, the process is membrane distillation and the feed water is provided to the permeable membrane at an elevated temperature relative to the filtrate and the continuous permeable graphene film acts to thermally insulate the filtrate side from the feed water side.

The feed water may contain a range of inorganic and organic species, such as for example a surfactant, oil or petroleum or residues of a surfactant, oil or petroleum product. Specific examples of inorganic species include Na⁺ and Cl⁻.

In one embodiment the feed water is industrial waste water or water for desalination. For example, the industrial waste water may be from mining, agriculture or material processing.

In one particularly preferred embodiment, the feed water is sea water and the contaminant is salt. he permeable membranes of the present invention are particularly suited for desalination processes, such as reverse osmosis and more particularly, membrane distillation.

The method is applicable also in cases of extremely high pH (above pH9 to about pH 13) or extremely low pH (below pH 5 to about pH2) or in cases where the feed water is acidic or basic outside physiological pH range (pH 5-9) however it will be appreciated that the method of filtration is applicable at any pH.

In the method of the present invention, the permeable graphene side of the membrane remains charge neutral over a wide range of pH's such as from pH2 to pH 13 or from pH 3 to 10 or from pH 4 to 9.

The contaminant to be filtered may be a hydrated or solvated ion. More particularly, the contaminant to be filtered is a hydrated or solvated ion having a radius larger than 0.9 nm³.

According to a sixth aspect, the invention provides a method of separating a feed solution containing hydrated or solvated ions comprising providing said feed solution to a permeable graphene film or permeable membrane according to the invention such that the feed water contacts the continuous permeable graphene film as a feed side, allowing water to pass through the permeable membrane to a filtrate side to provide a filtrate, and whereby the hydrated or solvated ions are retained on the feed water side.

In another aspect, the invention provides a continuous permeable graphene film comprising 1-40 layers of graphene and a having plurality of pores or channels extending through said film.

Preferably the pores have an opening size of 5-100 nm. Preferably, the pore density is homogeneous over the entirety of the film, and more preferably the pore density is 50 to 220 pores per μm.

More particularly, in this aspect, the invention provides a continuous permeable nanoporous graphene film comprising 1-5 layers of graphene and having a plurality of pores extending through said film, the pores have an opening size of 5-100 nm.

The invention also provides a method of preparing a deposited permeable nanoporous graphene film comprising the steps of heating a metal substrate and an excess of carbon source in a sealed ambient environment to a temperature which produces carbon containing vapour from the carbon source such that the vapour comes into contact with the metal substrate, maintaining a temperature for a time sufficient to form a graphene lattice, and flash cooling the graphene lattice under reduced pressure to form a deposited permeable nanoporous graphene film.

Preferably the heating is maintained in a heating zone and the flash cooling takes place in a cooling zone.

Preferably the ambient environment is air at atmospheric pressure or a vacuum. Most preferably, the ambient environment is air at atmospheric pressure.

In one embodiment, the ambient environment is air at atmospheric pressure. Although the present invention is described with reference to air, artificially prepared gases or combinations of gas that mimic the action of air could be used if desired. Such artificial combinations of gases could be used at pressures to mimic the effect achieved by air at ambient pressure.

In another embodiment, the ambient environment is a chamber evacuated prior to heating, preferably less than 1 mm Hg.

The metal substrate may be a transition metal substrate, for preference the metal substrate is nickel or copper, most preferably nickel. The metal substrate can be in any suitable form, for example a flat foil or wire.

If the metal substrate is nickel the ambient environment is air at atmospheric pressure. Preferably, the metal substrate is nickel of purity 99% and above, most preferably the metal substrate is polycrystalline nickel.

Alternatively, the metal substrate is copper and the ambient environment is an evacuated chamber prior to sealing and heating.

The carbon source may be advantageously being biomass or derived from biomass or purified biomass. The biomass or purified biomass may be for example a long chain triglyceride (fatty acid), such as soybean oil, or it may be a cellulosic material. Renewable biomass may be used. The carbon source may be in any form, such as liquid or solid form with liquid usually being considered advantageous.

The method is free from feedstock gases. “Feedstock gases” as used herein includes any purified gas typically used in CVD processes for etching, blanketing or as a carbon source material and the term specifically includes, but is not limited to hydrogen gas, argon gas, nitrogen gas, methane gas, ethane gas, ethylene gas and acetylene gas.

Preferably the step of heating employs a carbon excess environment. It is preferred that during the step of heating the metal substrate and carbon source are both located in the one heating zone.

Preferably the sealed environment is an inert container, such as a quartz, glass or other dielectric heat resistant container. Most preferably the sealed environment is contained in a quartz tube.

Preferably the metal substrate and carbon source are heated to a temperature sufficient to form a graphene lattice in the range 650° C.-900° C., such as 800° C. or 900° C. The temperature sufficient to form a graphene lattice is maintained for a suitable time, ideally 0-3 minutes.

Preferably flash cooling is at a rate of 25° C./minute-100° C./minute.

Preferably, the graphene lattice is flash cooled under reduced pressure by transferring the lattice from the heating zone to a cooling zone that is under vacuum.

The invention provides a continuous permeable nanoporous graphene film comprising 1-5 layers of graphene said film prepared by a method comprising the steps of heating a metal substrate and an excess of carbon source in a sealed ambient environment to a temperature which produces carbon containing vapour from the carbon source such that the vapour comes into contact with the metal substrate, maintaining a temperature for a time sufficient to form a graphene lattice, and then flash cooling the graphene lattice under reduced pressure to form a deposited permeable nanoporous graphene film.

In another aspect, the invention provides a continuous permeable graphene film having nanochannels and nanopores providing a fluid passage from one face of the permeable graphene film to the other. The film may contain for example 1-40 layers of graphene.

The invention also provides a permeable membrane comprising a permeable support membrane overlaid by a continuous permeable graphene film, said continuous permeable graphene film having a plurality of nanochannels and nanopores extending therethrough.

### BRIEF DESCRIPTION OF THE DRAWINGS

FIG. 1A shows the cross-sectional representations of nanoporous permeable graphene of the present invention.

FIG. 1B shows a cross-sectional representation of the structure of nanochannel permeable graphene suitable for preparing the permeable membranes of the present invention.

FIG. 2 shows the apparatus used to prepare the nanoporous and nanochannel permeable graphenes of the present invention.

FIG. 3A shows the time and temperature profile used to prepare the nanoporous permeable graphene of the present invention.

FIG. 3B shows the time and temperature profile used to prepare the nanochannel permeable graphene of the present invention.

FIGS. 4A and 4B shows respectively the growth of crystalline domains and the mismatching of edges of graphene sheets.

FIG. 5 shows a TEM of the nanochannel graphene of the present invention, identifying particularly the edge mismatch of the graphene sheets (a) scale is 50 nm, (b) scale is 10 nm.

FIG. 6 shows growth parameters for various graphenes, including nanochannel permeable graphene suitable for preparing the permeable membranes of the present invention

FIG. 7 shows different minimum precursor amount for graphene formation for different tube furnace dimensions.

FIG. 8. Schematic of permeable graphene film synthesis and its utilization as anti-fouling, water desalination membrane via membrane distillation. The schematic (a) illustrates the synthesis of permeable graphene using polycrystalline Ni substrate via an ambient-air CVD processes from renewable sources such as soybean oil. The synthesized permeable graphene film was wet transferred to commercial PTFE based MD membrane for water desalination testing. It is believed that the mechanism of water purification & desalination enabled by unique graphene features such as overlapping of graphene domains and grain boundaries (b). Moreover, hydrophobicity and out-of-plane thermal resistance properties of CVD graphene is utilized as an advantageous feature in forming anti-fouling, long-term flux stable MD membrane.

FIG. 9. Characteristics of permeable graphene films that enable permeation of water vapours and water desalination and purification. Several nanoscopic features in permeable graphene film enable water permeation and desalination. The microscopic morphology of the graphene film was investigated using SEM, revealing the graphene film on the PTFE membrane in (a) low-magnification, and (b) high-magnification. Many ripples on the surface of the graphene film are observed, and the high transparency of the graphene film allows one to observe the underlying PTFE membrane. TEM images in (c) low-magnification, and respective (d) bright-field and (e) dark-field images show many small graphene domains with many thick dark lines corresponding to the overlapping of grain boundaries which form the channels for the water vapour passage.

FIG. 10. Detailed TEM characterisation of overlapping domains forming nanochannel in permeable graphene films. (a) TEM image of overlapping domain boundary (darker contrast region) forming extended nanochannel in permeable graphene film. SAED patterns (and associated line profiles in supplementary information) confirm the labelled regions as (b) single layer graphene with rotation axis of 29.5°, (c) overlapped domains forming ˜250 nm wide nanochannel, (d) turbostratic bilayer graphene with rotation axes of −7.6° and 25.1°. The darker contrast region is confirmed as an overlapping misoriented graphene domain boundary, or nanochannel, due to the single layer to bilayer transition and shift in the respective rotation axes on either side of the feature. Inset shows representative diagram of an overlapping domain boundary with equivalent rotations of domains but narrow nanochannel width.

FIG. 11. Additional structural features of permeable graphene films. Additional characterization of the graphene films reveals their rough surface texture and variation in thickness. These features are favourable for generating a bottleneck region for water vapour permeation. The presence of multiple nanocrystalline domains suggests the existence of numerous channels for water vapour permeation. (a) An AFM topography image of the edge of a graphene film deposited on a mica substrate; the dark region at the left hand side of the image is the mica substrate; the lighter region is the graphene film, and the bright spots are most likely residue from the wet transfer process. (b) A relative height histogram of the AFM image (a). The high narrow peak around 0 nm height represents the mica substrate, the broader distribution represents the graphene film, and the tail up to heights of 18 nm most likely represents wet transfer process residue. (c, d) Raman spectral mapping analyses of the intensity ratios of ID/IG and 12D/IG.

FIG. 12. Comparison of the desalination performance of commercial MD membranes and permeable graphene based membrane in different contamination environments (high concentration of salt water, salt water with high concentration of SDS, salt water with high concentration of mineral oil). Water vapour flux and salt rejection performances of the commercial PTFE based MD membrane and the permeable graphene based membrane. (a) commercial PTFE based MD membrane and (b) permeable graphene based membrane in the DCMD process for 72 hours, with 70 gL⁻¹ of NaCl solution as feed. (c) Commercial PTFE based MD membrane and (d) permeable graphene based membrane with 70 gL⁻¹ NaCl solution and 1 mM sodium dodecyl sulfate (SDS) as feed. The flow rates of these DCMD tests were both maintained at 6 Lh⁻¹ in the feed and permeate stream. (e) Commercial PTFE based MD membrane and (f) permeable graphene based membrane in the DCMD process with a feed solution containing, 1 gL⁻¹ mineral oil with 70 gL⁻¹ of NaCl and 1 mM NaHCO₃ in the DCMD process for 48 hours. The feed and permeate temperatures were 60° C. and 20° C., respectively. The flow rates of these DCMD tests were both maintained at 30 Lh⁻¹ in the feed and permeate stream. The present results demonstrate that the permeable CVD graphene based membranes exhibit strong anti-fouling properties while enabling rapid water vapour permeation and good salt rejection.

FIG. 13. Comparison of the desalination performance of a commercial MD membrane and permeable graphene based membrane with unprocessed seawater from Sydney Harbour. Membrane distillation performance using unprocessed seawater from Sydney Harbour area. Water vapour flux and salt rejection performances of (a) a commercial PTFE based MD membrane and (b) the permeable graphene based membrane in the DCMD process for 72 hours. The feed and permeate temperatures were 60° C. and 20° C., respectively. The flow rates of all DCMD tests were both maintained at 30 Lh⁻¹ in the feed and permeate stream. The present results again demonstrate the strong anti-fouling nature of permeable graphene film with high and stable water vapour flux over a long operation time. Moreover, a stable, 100% salt rejection rate is maintained.

FIG. 14. Additional SEM images revealing the surface features and morphology of permeable graphene and commercial MD membrane. SEM image revealing large area uniform coverage graphene on top of commercial MD membrane consisting of polytetrafluoroethylene (PTFE) polymer, commercial PTFE based MD membrane/permeable graphene junction and SEM of pristine PTFE based MD membranes. (a) Large-area low-magnification image of permeable graphene film on PTFE membrane. It is evident that many ripple-like structures are present. (b) Boundary between graphene and PTFE membrane. (c) Higher-magnification SEM image of PTFE membrane, microporous web-like structure is evident.

FIG. 15. Additional TEM images revealing the overlapping of grain boundaries in few-multi layer graphene film used for membrane testing. TEM image revealing large area graphene on Cu TEM grids, (red arrow) pointing to the dark lines on TEM images representing the regions of mismatched overlapping of graphene grain boundaries

FIG. 16. TEM of images of predominately single or bilayer graphene with nanochannels. Single to bi-layer graphene with nanochannels were synthesized to clearly demonstrate the existence of the overlapping of graphene domain boundaries. A strip of a darker contrast region is representative of the nanochannels (red arrow).

FIG. 17. A montage of low magnification TEM images of predominately single or bilayer graphene on lacey carbon TEM grid. Regions showing extended lines of darker contrast, and highlighted with red in (b), are either folds of the graphene sheet or overlapping domain boundaries (nanochannels), which can be confirmed through SAED analysis. Multilayers are also visible as regions with darker contrast and defined sharp angled edges.

FIG. 18. Optical transmission spectrum of permeable graphene. Optical transmittance of permeable graphene film taken from glass slide after transfer. Sampling area was 2 cm². Transmittance of 85% suggests a few to multi-layer graphene film.

FIG. 19. Individual Raman spectra taken from selected areas in permeable graphene samples. Raman spectra suggest presence of multi-layer graphene with variation in number of layers in graphene.

FIG. 20. Testing set up for the water desalination and purification. Testing was carried out in a continuous cross flow system where permeable graphene film was placed in between the feed and the permeate side.

FIG. 21. Repeated MD experiments of pristine PTFE membrane with saline water, SDS/Saline water mixtures and mineral oil/Saline water mixtures. All the fouling experiments were repeated twice to demonstrate the reproducibility of pristine PTFE based membrane performance. (a, b) demonstrate the repeated experiments with saline water (70 gL⁻¹ of NaCl), (c, d) demonstrate the repeated experiments with SDS/saline water mixtures (1 mM SDS/70 gL⁻¹ of NaCl). The result shows rapid degradation of membrane performance is observed. Similarly, (e, 0 demonstrate the repeated experiments with mineral oil/Saline water mixtures (1 gL-1 mineral oil with 70 gL⁻¹ of NaCl and 1 mM NaHCO₃). The result shows, significant reduction in water vapor flux was observed, with degradation in salt rejection to 85˜90% over 48 hours with increasing in TOC level demonstrating the passage of oil through the membrane.

FIG. 22. Repeated MD experiments of permeable graphene membrane with saline water, SDS/Saline water mixtures and mineral oil/Saline water mixtures. All the fouling experiments were repeated twice to demonstrate the reproducibility of permeable graphene based membrane performance. (a, b) demonstrate the repeated experiments with saline water (70 gL⁻¹ of NaCl), (c, d) demonstrate the repeated experiments with SDS/saline water mixtures (1 mM SDS/70 gL⁻¹ of NaCl). The result shows stable water flux with >99.9% salt rejection is achieved for 72 hours of MD operation. Similarly, (e, demonstrate the repeated experiments with mineral oil/Saline water mixtures (1 gL-1 mineral oil with 70 gL-1 of NaCl and 1 mM NaHCO₃). In this case, the TOC of the permeate water was also monitored to show the oil rejection over 48 hours of MD operation. The result shows, slight reduction in water vapor flux was observed, with salt rejection of >99.9% along with stable oil rejection over 48 hours.

FIG. 23. Membrane performance of permeable graphene at different cross flow and with different feed temperatures. To investigate the factors affecting the water vapor transport in permeable graphene based membrane, different process parameters were varied, such as (a) cross flow rate of supplied water and (b) feed water temperatures to see the changes in water vapor permeation. The results show that water vapor flux increased as the cross flow rate of the water stream was increased. Similarly, as the temperature of the feedwater was increased, water vapor flux was also increased. In all cases, stable water vapor flux was maintained at the permeate side for the permeable graphene based membrane throughout the duration of MD operation. All the tests were done with saline solution (70 gL⁻¹ of NaCl).

FIG. 24. Commercial PVDF based MD membrane test with mineral oil/saline water mixture and SDS/saline water mixtures. Another widely used MD membrane is PVDF based MD membrane (Durapore). Commercial PVDF based membrane test under (a) mineral oil/saline water mixture and (b) SDS/saline water mixtures was performed to demonstrate the fouling problem against low surface tension liquids are not just restricted to PTFE based MD membrane but it is a general problem for MD membranes. The results shows that significant flux reduction is observed for both cases of (a) mineral oil/saline water mixture and (b) SDS/saline water mixtures along with decrease in salt rejection, showing the membrane failure within a short MD operation period.

FIG. 25. Mineral Oil/Saline water mixture used for experiments with particle size distribution and after test photo of permeable graphene with mineral oil/saline water mixture. (a) shows the photo graph of the mineral oil/saline water mixture used in the experiments, as one can see stable oil emulsion has been formed. (b) shows the oil size distribution curve showing oil contents were mostly 1 to 3 μm in sizes along with minority content with sizes from 78 nm to 180 nm. (c) is after-test photograph of the permeable graphene. Over 48 hours of filtration tests, significant oil contents are visible on the surface of the graphene film.

FIG. 26. Long term membrane performance of permeable graphene with sea water collected from Sydney Harbour for 120 hours. Long term (120 hours, 5 days) membrane performance test was performed with sea water collected from Sydney Harbour to demonstrate the practical applicability and long term stability of permeable graphene based membrane. The results show that through permeable graphene, stable water flux as well as stable salt rejection of >99.9% was achieved over 120 hours of MD operation revealing permeable graphene's excellent capability as anti-fouling, long term stable membrane material.

FIG. 27. AFM topography measurement of a permeable graphene film. The cross section profile of the graphene film on the mica substrate was extracted from FIG. 3a. AFM topography measurement indicates that the permeable graphene film surface is rough, which is reflected by the variation in the height of the graphene film ranging from 0.7 nm to 3.7 nm. Wet transfer residue was several nm high. Rough surface of permeable graphene film creates favourable morphology for water vapor permeation.

FIG. 28. Additional benefits of incorporating permeable graphene in MD membrane

Shows a MD experiment with high temperature of feed water. (Feed water temperature 90° C.) The permeated vapor flux and the temperature of the feed at the surface of the membrane and permeated vapor temperature were recorded over 4 hours of MD operation. All the tests were done with saline solution (70 gL⁻¹ of NaCl). Then the difference in temperature of the actual feed water and permeated vapor flux were calculated over MD operation time. Firstly, (a) water vapor flux curve shows that wetting behaviour for pristine PTFE membrane, exhibits a sharp increase in water vapor flux over 4 hours, the membrane is failing to maintain stable performance at high feed temperature. However, when permeable graphene film was incorporated, high and stable water vapor flux was maintained for the duration of MD operation, demonstrating superior membrane stability of permeable graphene based membrane under high temperature gradient, which can potentially widen the stable operation temperature window of the MD process. (b) shows the actual temperature difference recorded for the pristine PTFE membrane and permeable graphene based membrane. The results show that permeable graphene was able to maintain a higher temperature gradient compared to pristine PTFE membrane throughout the duration of MD operation, demonstrating potential thermal benefits of using graphene film in MD process.

FIG. 29. Mechanical strength measurement of permeable graphene/PTFE membrane and pristine PTFE membrane. To investigate the changes in mechanical strength of the membrane after the permeable graphene incorporation, mechanical strength tests were performed for the (a) pristine PTFE membrane and after the (b) permeable graphene incorporation. The results show the marginal improvement in the mechanical strength of the membrane when permeable graphene film is incorporated. Improvement was marginal due to thin nature of the permeable graphene film (few nm thick) compared to the bulk (120 μm thick) PTFE membrane.

FIG. 30. Contact angle measurements of permeable graphene film/PTFE membrane and commercial PTFE membrane. Top: Graphene/PTFE membrane. CA 81.3+/−0.51 deg. Bottom: PTFE membrane only. CA 131.32+/−8.63 deg. Permeable graphene film is shown to be more hydrophilic than PTFE membrane.

FIG. 31. Raman analysis of the after-test samples under SDS/saline water mixtures. To qualitatively visualise different adsorption behaviour of the SDS to pristine PTFE membrane and permeable graphene surface, Raman analysis was performed on after test (72 hours) samples which were tested under SDS/saline water mixtures. (a, b) shows the part of the after-test samples of (a) pristine PTFE membrane and (b) permeable graphene/PTFE membrane. (c, d) shows the individual Raman spectrum of after test (c) pristine PTFE membrane and (d) permeable graphene/PTFE membrane. Then to qualitatively verify the differences in adsorption behaviour, Raman areal mappings of SDS peak intensities were carried out on after test (e) pristine PTFE membrane and (f) permeable graphene/PTFE membrane samples. The results show that significantly higher SDS peak intensities were observed for pristine PTFE membrane compared to the permeable graphene/PTFE membrane case. These findings suggest a significantly higher SDS adsorption on pristine PTFE membrane and reveal different adsorption interactions between SDS molecules with PTFE membrane surface and the permeable graphene surface.

FIG. 32. Zeta potential measurement of permeable graphene and pristine PTFE membrane. Zeta potential measurements show that the graphene films of the present invention exhibit almost negligible charge (charge neutral) under varying pH conditions shown by near flat line around 2-4 mV with varying pH conditions. A pristine PTFE membrane shows negative surface charge under varying pH condition.

FIG. 33. Cost analysis of integrating 1 cm² of permeable graphene onto PTFE membrane (US$).

FIG. 34. Comparison of key physicochemical properties between light crude oil and mineral oil used as feed solution.

FIG. 35. Composition analysis of sea water from Sydney harbour

### DESCRIPTION

The present invention relates to a low-cost, highly-effective nanoporous and nanochannel graphene and to membranes prepared from these graphenes, particularly membranes which are suitable for water filtration and purification, including water desalination. The graphene films are synthesized in a single-step, rapid thermal process in an ambient-air environment, and can use a renewable form of biomass, soybean oil, as the precursor. This process does not require any compressed gases. More importantly, graphene developed in this process does not involve any post-synthesis processing to create nanopores in the graphene film for water transport.

Rather the graphene layer of the membranes of the present invention exhibit a unique combination of microstructure features which enable water vapour permeation and facilitate its favourable performance in desalination processes such as membrane distillation (MD) which requires hydrophobic membranes.

Reverse osmosis (RO) and MD are techniques by which water can be purified—in a practical sense, these are methods of desalination. Both involve brine or other kinds of saline solution into contact with a membrane, and collecting desalinated, ideally potable, water from the on the filtrate side of the membrane.

RO is a pressure driven process, in which applied pressure is used to counter the natural flow gradient between the high osmotic pressure in the saline feed side and the low osmotic pressure in the pure filtrate side. Because of the high pressure applied to RO membranes, they are particularly susceptible to contamination and blockage. Achieving and sustaining the necessary high operating pressures is also complex and requires significant amounts of energy. The use of RO membranes for the desalination of water also results in the production of retentate solutions that have very high concentrations of NaCl, for example. These ultra concentrated salt solutions are very harmful to the environment and present a significant problem in terms of disposal.

MD, in contrast, is a thermally driven process and gives rise to solutions having to be disposed of which in itself can be harmful to the environment. In this case, heat, rather than pressure is used to counter the differential osmotic pressure. MD can be run at relatively low temperatures, for instance, the type of temperatures that saline solutions can achieve by simple solar heating. It is also feasible to operate MD systems in such a way that quantities of extremely saline material are not produced.

In MD, water vapour passes through the membrane. As such, aside from the requirement that the membrane is hydrophobic, the process is otherwise relatively insensitive to the chemical nature of the membrane, but the pore size is important as undesirable species must not be permitted passage through the membrane.

MD is a rapidly emerging technology that is particularly promising for the treatment (desalination and purification) of seawater, industrial effluents and brine obtained from reverse osmosis (RO) and various desalination processes.⁷ In the MD process, water purification is driven by a vapour pressure gradient across a porous and hydrophobic membrane. This situation is created by parallel flows of a hot feed solution and permeate stream, where water vapour is formed at the interface of the membrane's hot feed side and is transported to the opposing cold permeate side.⁸

Key advantageous features of the MD process include water production almost independent of the feed solution salinity, and the potential to reject majority of non-volatile constituents, such as dissolved salt, organics, colloids (technology which has potential to produce clean water in single filtration process) and the ability to utilize low grade waste heat to drive the process. These merits enable MD to be a promising green technology for zero liquid discharge desalination and purification processes in various water treatment applications.⁹

The permeable membranes of the present invention are formed from a permeable graphene layer disposed upon a conventional MD membrane. The permeable graphene layer has nanochannels formed from controlled edge mismatches. The edge mismatches between each layer permit the ingress of water into the planar space between the graphene sheets, which are spaced apart by about 0.34 nm, a spacing serendipitously well suited to the passage of a small species such as water, while rejecting larger species such as hydrated ions or larger molecules. The graphene layer is retained on the MD membrane via non-bonded interactions, no other mechanism is needed to maintain adhesion. The MD membrane has larger pores than the graphene, and as such does not participate in the rejection of larger species, it function is to provide mechanical support for the atomically thin graphene layer.

As such, the morphology of the graphene layer is critical to the success of the present invention. The present invention utilises as a starting point the basic process of graphene synthesis disclosed in the Applicant's earlier application PCT/AU2016/050738, the contents of which are incorporated herein by reference.

It has been discovered that by careful control of the free carbon density in the deposition chamber, and by cooling the deposited material under vacuum with a controlled predetermined temperature profile, it is possible to control the morphology of the resultant graphene.

The processes for forming both the simple nanoporous graphene of the present invention and the nanochannel graphene of the present invention both have the same common steps up until the end of the annealing process, with the differences taking place in the cooling steps.

It has been discovered that by careful control of the free carbon density in the deposition chamber, and by cooling the deposited material under vacuum with a controlled predetermined temperature profile, it is possible to control the morphology of the resultant graphene to produce either a porous or a nanoporous form of graphene, both of which have excellent potential for use as a filter or permeable membrane.

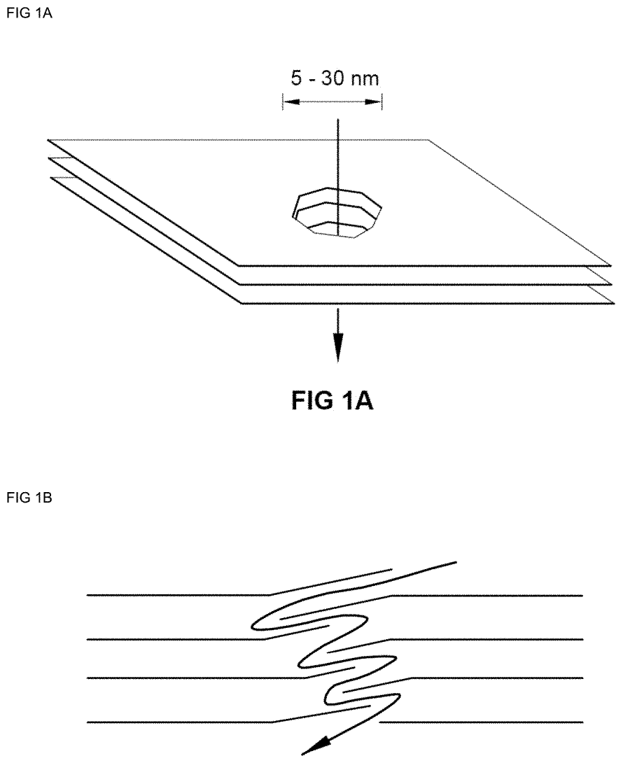

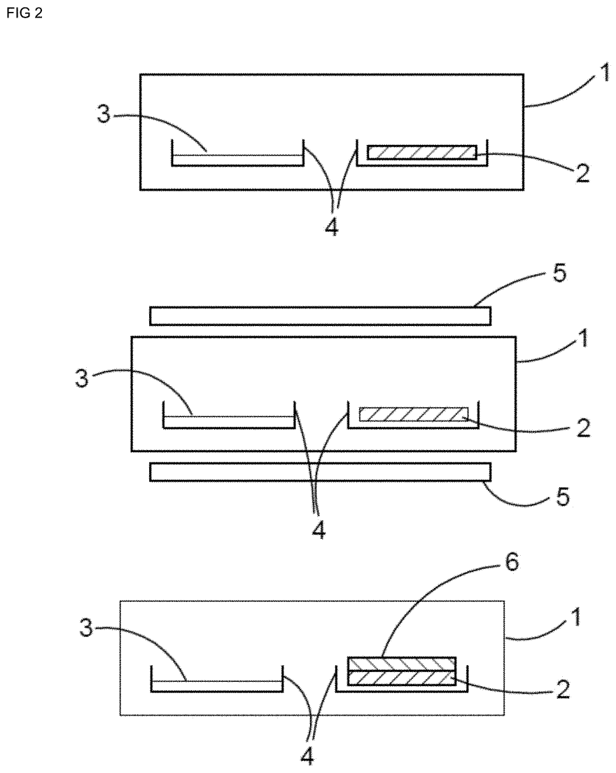

In one type of morphology, the graphene film of the present invention is 1-5 layers thick and has pores of around 5-100 nm width which run directly across the 1-5 layers graphene, i.e. the pores are 5-100 nm wide and 1-5 graphene layers deep respectively. This is referred to herein as “nanoporous graphene”. The structure is illustrated in FIG. 1a.

In the other type of morphology, the graphene film is 2 or more (say 2-10) layers of graphene and the permeability is provided by nanochannels. This is referred to herein as “nanochannel graphene”. The nanopores are structurally more complex than the simple pores, but stem from the modifications to simple pores during the deposition process. A cross section of the nanochannel region is illustrated in FIG. 1b.

Without wishing to be bound by theory, it is believed that during the annealing stage, graphene begins to form on the metal substrate at a number of nucleation sites, and individual discrete nanocrystalline domains begin to form. The orientation of these domains may or may not be aligned. These are seen in FIG. 4a. As each of these nano crystals grow during the annealing phase, their edges move outwards, as shown by the arrows. Eventually, the nanocrystalline domains begin to encroach along each other. If the domains happen to be aligned, individual nanocrystalline domains will join up in a manner that is referred to as “perfect stitching”. Where perfect stitching occurs, two discrete nanocrystalline domains will form a single nanocrystalline domain. Each nanocrystalline domain is grown to a size of around 100 nm to 500 nm.

The nanochannel arise as a result of nanocrystalline zones of graphene forming within each continuous graphene. Each subsequent layer of graphene has its own nanocrystalline zones and the subsequent overlay in some places of mismatched layers of the continuous film results in the establishment of tortuous nanochannel pathways which run across the 2-10 layers of graphene.

However, if the domains are not aligned, or in other words, ‘mismatched’ and the crystals continue to grow, then one of the nanocrystalline domains will overlay itself over another. FIG. 4b illustrates the growth of mismatched graphene domains. The graphene sheets are separated by about 0.37 nm.

In the present invention, once the graphene annealing stops, and vacuum is applied, entrained gases in the system below the graphene are drawn out through the graphene film. The “snap cooling” of the subsequently porated graphene leads to the recovery of the simple porous graphene.

In the other aspect of the present invention, nanoporous graphene, the mechanism up until the formation of the pores is necessarily the same, however, the delay phase, which takes place at high temperature, does not “snap freeze” the porous graphene structure, but rather, allows for some continued growth reaction. Limited regrowth of the crystalline domains results in the 5 nm to 100 nm pores being filled up with graphene sheets and the formation of mismatched edges near the grain boundary areas. In this way, regions are formed which have mismatching edges in close proximity through all the layers of the film, as per FIG. 1b.

Water molecules, for instance, are able to pass in the channels between graphene layers and can do so at the mismatched edges. If a mismatch is present in an adjacent layer, the water molecule can move through that also. The closer the regions of mismatch, the shorter the tortuous path that must be taken by the molecule to pass through the graphene layer. In the present invention, because of the previously formed pores, the nanochannel graphene has mismatches in all layers in close proximity.

The channel sizes of the nanochannel graphene is therefore between 0.37 nm (the usual stacking distance of the graphene sheets) and up to about 3 nm, and initial data suggests the nanoporous graphene functions as a 0.37-3 nm membrane.

In addition, by controlling this slow cooling stage, the graphene sheet thickness may also be controlled. For example, the slower the cooling, the thicker the sheets and less overlap and overlapping of the graphene as well.

The graphene morphology particularly suited for use in the preparation of permeable filtration membranes is a graphene film with 2 or more (say 2-10) layers of graphene where the permeability is provided by nanochannels. This is referred to herein as “nanochannel graphene”. A cross section of the nanochannel region is illustrated in FIG. 1b.

As described above, the initial steps of the forming the nanoporous and nanochannel graphene materials are the same. The steps are now described with reference to the nanochannel graphene materials. The method of the present invention is carried out in a sealed container (1) in an oven. The general configuration is illustrated in FIG. 2

Typically, the container (1) is an inert tube, for example a tube made from quartz, alumina, zirconia or similar. The size of the container is chosen so as to be relatively compatible with the substrate being coated, that is, it is desirable to minimize the amount of dead space in the container.

The oven can be any type of oven suitable for heating the container to temperatures of the order of 800° C. One type of suitable oven was found to be a thermal CVD furnace (OTF-1200X-UL, MTI Corp), which is adapted to heat tubular vessels. One example of a suitable tubular vessel is a quartz tube of 100 cm length and 5 cm diameter.

The method of the present invention involves placing a growth substrate (2) and carbon source (3) in relatively close proximity to one another in the container. They may be placed directly into the tube, or more usually, are placed in inert crucibles (4), such as alumina crucibles, prior to placement in the tube. The container is then sealed and placed in the oven, or alternatively placed in the oven and sealed. When the metal is Nickel, no gas evacuation or flushing is required and the atmosphere in the sealed container at the commencement of the process is air. An ordinary mechanical seal will suffice. There is no need for the container to be sealed to withstand significant pressure differences.

The metal substrate (metal foil or metal wire) and carbon source are placed adjacent each other. The exact distance is not critical, as long as both the substrate and carbon source are within the heating zone. Due to the rapid thermal expansion of the vapours from the carbon source, the concentration of vapours will be fairly consistent across the heating zone. A degree of vacuum can be applied to aid in the flow of precursors within the heating zone if required.

The positioning of the carbon source and substrate within the container should be such that when the container is in the oven, the carbon source and substrate are both simultaneously within the heating zone (5).

The substrate is a metal substrate, most desirably a transition metal substrate, for example a nickel substrate. It has been established by the inventors that there is little advantage to be gained from using nickel that is higher than 99.5% purity. 99.9% pure nickel or higher are suitable for use in the present invention, but they produce no discernible advantage over 99.5% or 99% pure nickel, which is available at a fraction of the cost of higher purity material.

The substrate (2) can be quite thin. One type of suitable substrate is polycrystalline Ni foil (25 μm, 99.5%,) or also polycrystalline Ni foil (25 μm, 99%).

Without wishing to be bound by theory, it is believed that Ni acts as a catalyst for the breakdown of hydrocarbon species into smaller building units essential for the synthesis of graphene.

Other transition metals can be used with minor modification. For instance, while Nickel is a useful substrate under ambient atmospheric conditions, Copper can be used as a substrate for the growth of graphene by evacuating any ambient air within the tube at the start of the process. The remainder of the process is otherwise the same. However, regardless of the substrate, the methods of the present invention avoid the use of expensive compressed gases as required in prior art methods.

The use of a Nickel substrate does not appear to be adversely affected by the presence of air, however, Copper substrates provide more growth of graphene domains in the absence of any gas, i.e. without air. In such a case, the amount of carbon needs to be adjusted to compensate for the absence of oxygen which would otherwise react with available carbon. Substrates that are more susceptible to competing oxidation reactions would advantageously be reacted under conditions requiring the additional evacuation step.

After cooling, the substrate (2) was removed and the graphene (6) grown thereon was analysed, including by TEM microscopy.

The carbon source can be any source of material that provides volatile carbon at temperatures between 200-650° C. at ambient pressures. For instance, animal or vegetable fat in unprocessed form have both been found to be useful.

One particularly useful source of carbon is raw soybean oil, which is a triglyceride of formula C₁₈ H₃₆O₆. More abundant biomass and industrial by-products, for example, cellulosic materials, may be used. The present inventors have established that there is no need to use highly purified material as the carbon source.

It has been found that in order to obtain the nanochannel form of graphene described herein, a predetermined “slightly carbon rich or carbon rich” environment needs to be created within the deposition chamber. The molar quantity of carbon per unit volume within the deposition chamber was found to be an important parameter. In order to form the nanochannel graphene film, it was found to be necessary to create a deposition environment which is slightly more carbon rich than the environment required to form simple graphene films in the Applicant's earlier filed PCT/AU2016/050738. However, oversaturation of the chamber with carbon is to be avoided as that will result in very thick graphene.

The following calculations explain with reference to soybean oil and 0.00196 m³ chamber how the amount of carbon within the chamber is calculated and the suitable range of carbon rich environments for preparing the porous and nanoporous graphene films of the present invention.

First, it is necessary to calculate the oxygen consumption in the reactor during the growth using soybean oil. The oil degrades to carbon, but a significant portion is converted to carbon dioxide, which is not reactable under the present conditions to give graphene.

### Carbon Excess to Form Simple Graphene Film

An optimal amount of soybean oil (a liquid at ambient temperatures) as a carbon source required to form a simple few layer graphene film was determined experimentally for a chamber of 0.00196 m³ to be 0.14 mL. 0.14 mL can be regarded for this chamber as defining a “carbon neutral” environment, i.e. not so carbon-poor as to lead to oxidation of the metal, nor sufficiently carbon rich to allow porous or nanoporous graphene to form.

Using the average density of soybean oil (0.917 g mL⁻¹) and an average chemical composition (linoleic acid—52%, oleic acid—25%, palmitic acid—12%, linolenic acid—6%, stearic acid—5%), it is calculated that ˜0.0081 mol of C and ˜0.0151 mol of H are initially present in the growth chamber. The amount of oxygen provided by the soybean oil is around ˜0.0001 mol so can be disregarded.

The ambient air process employed in the case of nickel means that the oxygen in the deposition chamber needs to be considered, as this will be involved in the thermal degradation of the soybean oil. This breakdown of soybean oil will be a complex process yielding numerous molecular fragments which consume O₂ through different reaction pathways.

The likely combustions reactions include:

| | |
|---|---|
| C + O₂ → CO₂ | 1 C for 1 O₂ -- (1) |
| 4CH₃ + 7O₂ →4CO₂ + 6H₂O | 1 C for 1.75 O₂ -- (2) |
| 2C₂H₂ + 5O₂ → 4CO₂ + 2H₂O | 1 C for 2.5 O₂ -- (3) |
| 4C₂H₅ + 13O₂ → 8CO₂ + 10H₂O | 1 C for 3.25 O₂ -- (4) |
| 2C₂H₆ + 7O₂ → 4CO₂ + 6H₂O | 1 C for 3.5 O₂ -- (5) |
| 2H₂ + O₂→2H₂O | solely consumes O₂ -- (6) |

Using the growth chamber dimensions and STP conditions, it is calculated that 0.0168 mol O₂(g) is present. Also, it is noted that at the temperatures involved in the ambient-air process, CO₂ does not undergo further decomposition.

If O₂ was only consumed through the reaction of C (reaction (1) above), then O₂ would be slightly in excess, with a remainder of 0.0087 mol. However, all other reaction pathways have a greater consumption rate of O₂. For instance, if O₂ was solely consumed through the reaction of C₂H₅ (reaction (3) above), then all the O₂ will be expended and C will be in excess with a remainder of 0.0035 mol. All these reaction pathways will likely proceed, and so the combined consumption of O₂ will yield an excess of C in the chamber. The amount of carbon source used in the experiment—0.14 mL of soybean oil is sufficient to just consume the 02 in the growth chamber, yielding an excess of C from which the present graphene can form. The excess used to form optimal graphene can be quantified as 0.0035 mol C per 0.00196 m³, or 0.00179 mol C per litre excess, i.e. 0.00179 mol C per litre available for graphene deposition.

### Carbon Excess to Form a Permeable Graphene Film

In order to form a permeable graphene both nanoporous and nanochannels, excess soybean oil, around 0.15 or 0.19 ml, was found to be required per 0.00196 m³. This additional 0.01-0.05 ml of soybean oil over and above 0.14 mL goes directly to the available carbon for deposition, since the oxygen in the chamber is largely consumed by the base quantity of 0.14 mL soybean oil.

Soybean oil is predominantly a Cis oil with a weighted average MWT of around 278. 0.14 mL of soybean oil corresponds to about 0.008 moles of carbon, so an extra 0.01 mL will add around an extra 0.0006 moles of carbon, and an extra 0.02 mL will add an extra 0.0012 moles of carbon to the deposition chamber.

Thus, using 0.15 mL will result in 0.0041 (0.0035+0.0006) moles of carbon per 0.00196 m³ or 0.00209 moles excess C per litre.

Using 0.19 mL will result in 0.0059 (0.0035+0.0024) moles of carbon per 0.00196 m³ or 0.003 moles excess C per litre.

Thus, a carbon environment comprising about 0.002 mol C per litre excess carbon—about 0.0018 to 0.003 moles excess C per litre of chamber volume should be used. Tables 1 and 2 provide a guide for calculation of the precursor amount depending on the length of tube that is used.

It will be appreciated by those skilled in the art that different carbon sources (such as different oil compositions) will lead to different precursor amounts required for graphene growth. Similarly, different chamber sizes will require different precursor amounts for graphene growth, however the principles explained herein will enable the correct amount of precursor to be calculated.

### Method of Forming Nanoporous Graphene

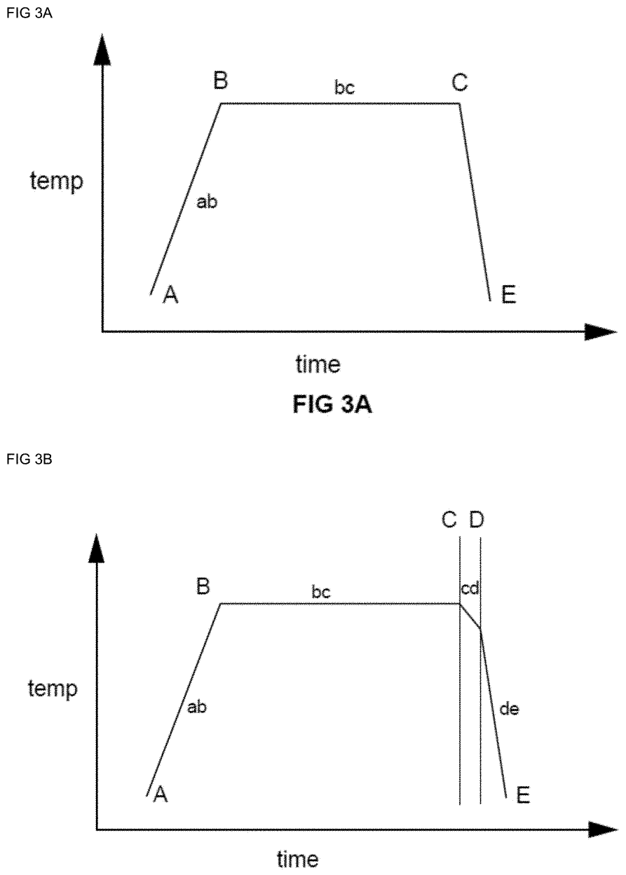

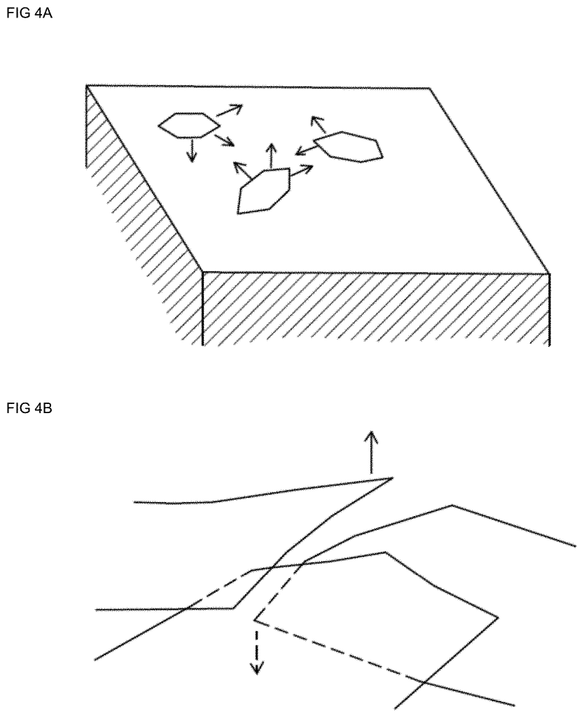

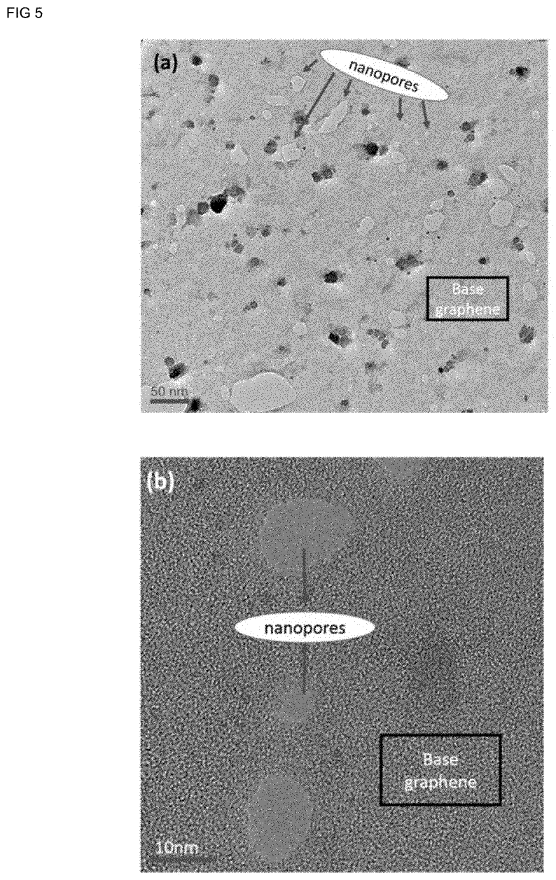

The carbon source is sealed in the chamber along with the substrate and heating source at ambient temperatures. This is shown in FIG. 3B at point A.

The furnace temperature is then raised to around 800° C. (B) over a period of 20-30 minutes. A typical ramping rate, shown at (ab) is from 25-35° C./min. During the ramping stage (˜300° C.-350° C.) the precursor is vaporized and the long carbon chains in the soybean oil begin to be broken down into gaseous carbon building units via thermal dissociation. Those skilled in the art will appreciate that the precise dissociation temperature will differ based upon the chemical and physical properties of carbon source precursor material. Simultaneously, gaseous carbon building units diffuse throughout the tube and towards the Ni foil growth substrate. As the temperature in the furnace gradually increases to 800° C., the carbon precursor is further broken down into simpler carbon units for graphene generation on the surface of metal substrate. In addition, as the temperature rises the carbon solubility in Ni increases and the carbon building units begin to dissolve into the Ni bulk. From 500° C. a graphitization process takes place where carbon atoms are starting to arrange themselves in sp² configuration. From 500° C. to 800° C. graphene lattice is shaped.

Graphene formation is observed to take place from 650° C., although the best quality graphene (in terms of low defects) is obtained from about 800° C.

Once the desired temperature is reached, the furnace is held at that temperature, for example, 800° C. (for 10˜15 min for 99.5% purity Ni foil) to enable growth. Graphene grains enlarge during this annealing process. The annealing time (bc) can be reduced by using lower purity films. For instance, the annealing time can be reduced to around 3 minutes if 99% purity Ni foil is used.

To form the nanoporous graphene of the present invention, the process is conducted as described above, using a slightly carbon rich environment, up until the completion of the annealing step C. The annealing step is conducted at atmospheric pressure (i.e. no pressure control other than sealing the tube). Once annealing is complete, the sample is immediately removed from the heating zone (generally, the oven) and moved to a cooling zone where a vacuum is applied and the sample is flash cooled at a rate of around 20-30° C. per minute, more typically around 25° C. per minute (or as quickly as practicable without damaging the apparatus) under the application of vacuum. During this step unconsumed gases are removed from the tube before cooling commences and halts graphene growth. Because of the rapid cooling, the sheet thickness is 1-5 graphene layers. Pore size is 5-100 nm.

### Method of Forming Nanochannel Graphene

To form the nanochannel graphene, the process is conducted as described above, using a carbon rich environment, up until the completion of the annealing step.

As before, the furnace temperature is then raised to around 800° C. (B) over a period of 20-30 minutes. A typical ramping rate, shown at (ab) is from 25-35° C./min.

Once the desired temperature is reached, the furnace is held at that temperature, for example, 800° C. (for 10˜15 min for 99.5% purity Ni foil) to enable growth. This annealing process takes place for an annealing time (bc).

The annealing step in the process above is conducted at atmospheric pressure (i.e. no pressure control other than sealing the tube). The process is described with reference to FIG. 3B. Once annealing is complete at (C), a delay step, (cd) is employed but before flash cooling begins at (D).

During this delay step, which is typically from about 1 to 5 minutes, the heat source is turned off and a vacuum is applied at (C), but the substrate and chamber are retained in situ. The rate of cooling during this time period is between around 10° C. per minute, more beneficially around 0˜10° C. per minute.

The length of time of the delay (cd) phase determines the exact nature of the nanochannel structure. Once the delay phase is completed, at D, the chamber is removed from the oven and allowed to flash cool (de) down to room temperature at a rate of around 20-30° C. per minute, more typically around 25° C. per minute (or as quickly as practicable without damaging the apparatus) under the application of vacuum.

The slower rate of cooling also results in a thicker graphene, typically 2-10 layers, with a channel size of 0.37-3 nm.

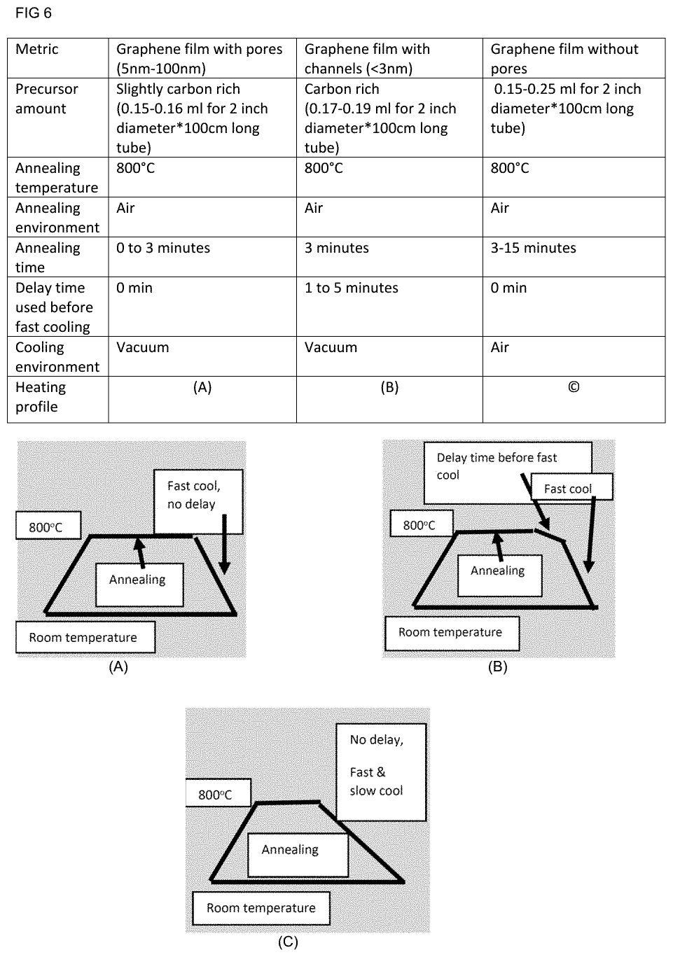

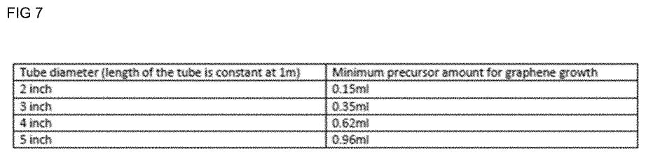

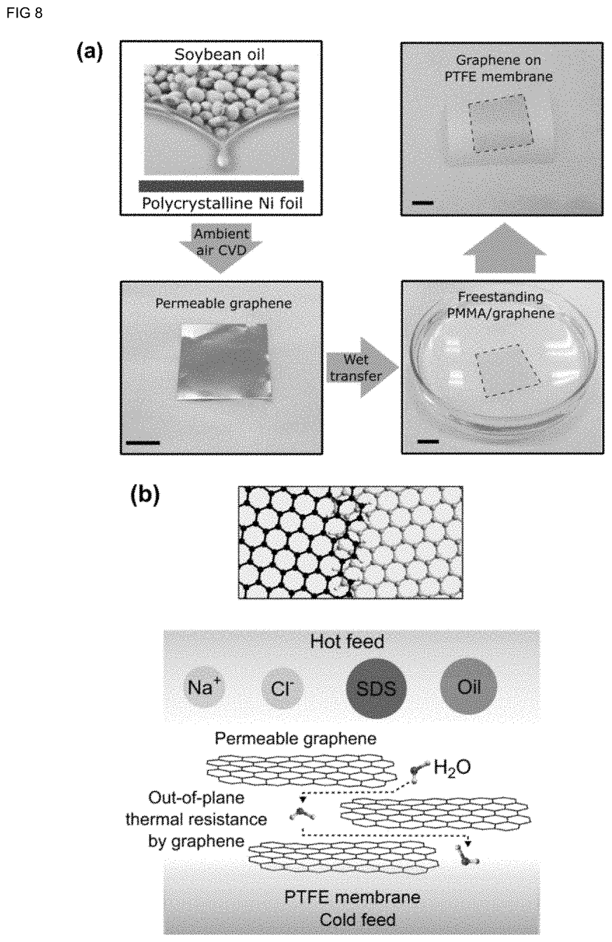

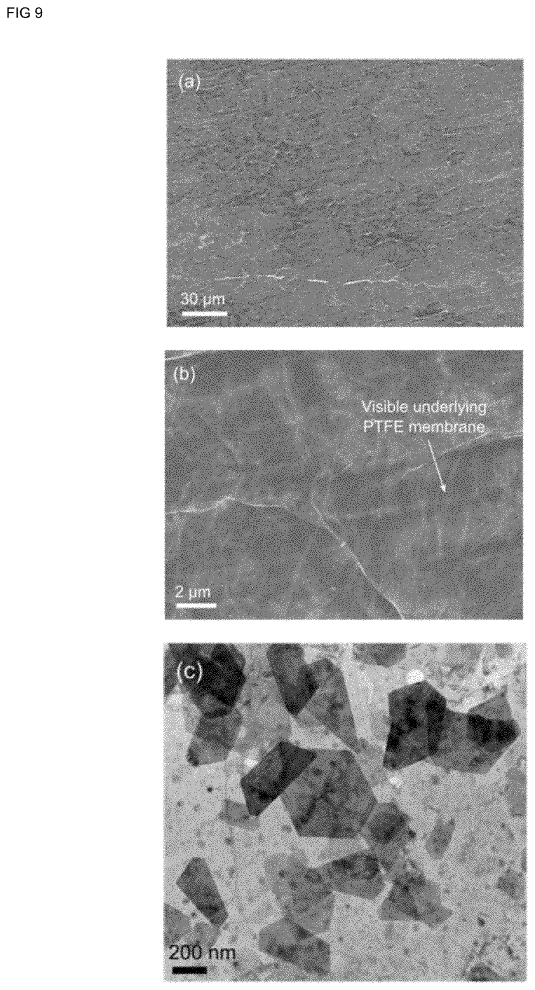

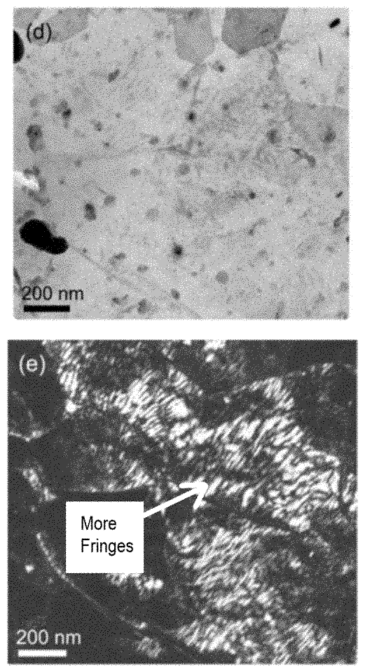

Growth conditions are summarised in FIG. 6 for a range of graphenes, including impermeable graphene, nanoporous graphene and the nanochannel graphene useful in the membranes of the present invention.

### Method of Forming a Graphene Containing Both Nanochannels and Nanopores

The mechanism of formation of permeable graphenes is describes in detail above. It has been noted that if the process of forming nanochannel graphene is halted in the early stage of growth, it is possible to obtain a graphene film that has both nanopores and nanochannels. The longer the growth process is allowed to continue as described for the nanochannel graphene, the greater the extent of nanochannel formation and the lower the probability of obtaining pores in the graphene.

### Mechanism of Formation of Permeable Graphenes

Without wishing to be bound by theory, it is believed that during the annealing stage, graphene begins to form on the metal substrate at a number of nucleation sites, and individual discrete nanocrystalline domains begin to form. The orientation of these domains may or may not be aligned. These are seen in FIG. 4a. As each of these nano crystals grow during the annealing phase, their edges move outwards, as shown by the arrows. Eventually, the nanocrystalline domains begin to encroach along each other. If the domains happen to be aligned, individual nanocrystalline domains will join up in a manner that is referred to as “perfect stitching”. Where perfect stitching occurs, two discrete nanocrystalline domains will form a single nanocrystalline domain. Each nanocrystalline domain is grown to a size of around 100 nm to 500 nm.

A nanochannel arises as a result of nanocrystalline zones of graphene forming within each continuous graphene. Each subsequent layer of graphene has its own nanocrystalline zones and the subsequent overlay in some places of mismatched layers of the continuous film results in the establishment of tortuous nanochannel pathways which run across the 2-10 layers of graphene.

However, if the domains are not aligned, or in other words, ‘mismatched’ and the crystals continue to grow, then one of the nanocrystalline domains will overlay itself over another. FIG. 4b illustrates the growth of mismatched graphene domains. The graphene sheets are separated by about 0.37 nm.

In the present invention, once the graphene annealing stops, and vacuum is applied, entrained gases in the system below the graphene are drawn out through the graphene film. The “snap cooling” of the subsequently porated graphene leads to the recovery of the simple porous graphene.

As discussed above, water molecules, for instance, are able to pass in the channels between graphene layers and can do so at the mismatched edges. If a mismatch is present in an adjacent layer, the water molecule can move through that also. The closer the regions of mismatch, the shorter the tortuous path that must be taken by the molecule to pass through the graphene layer. In the present invention, because of the previously formed pores, the nanochannel graphene has mismatches in all layers in close proximity.

The channel sizes of the nanochannel graphene is therefore between 0.37 nm (the usual stacking distance of the graphene sheets) and up to about 3 nm, and retention data shown below in more detail suggests the nanoporous graphene functions as a 0.37-3 nm membrane.

In addition, by controlling this slow cooling stage, the graphene sheet thickness may also be controlled. For example, the slower the cooling, the thicker the sheets and less overlap and overlapping of the graphene as well.

The use of a Nickel substrate does not appear to be adversely affected by the presence of air, however, Copper substrates provide more growth of graphene domains in the absence of any gas, i.e. without air. In such a case, the amount of carbon needs to be adjusted to compensate for the absence of oxygen which would otherwise react with available carbon. Substrates that are more susceptible to competing oxidation reactions would advantageously be reacted under conditions requiring the additional evacuation step.

After cooling, the substrate (2) was removed and the graphene (6) grown thereon was analysed, including by TEM microscopy.

### Permeable Graphene-Based Membrane & Mechanism of Water Vapour Permeation Through Overlapping Grain Boundaries

The permeable graphene membrane is grown by an ambient-air CVD process, described in more detail above and elsewhere,⁶ and then wet-transferred to a commercial Polytetrafluoroethylene (PTFE) MD membrane. This process is described in FIG. 8 (part a). Unlike conventional CVD methods, ambient-air graphene synthesis technique does not require any expensive and explosive purified compressed gases.^{19, 20} The source for the graphene growth is replaced with a low-cost, safe and renewable biosource such as soybean oil. The ambient air CVD process, enables the growth of continuous graphene films with a high density of nanocrystalline grain boundaries on polycrystalline Ni substrate, which are desirable as water vapour permeable channels. The graphene is then wet-transferred onto a conventional supporting commercial PTFE MD membrane. A PMMA-assisted transfer can be used, and PMMA is removed before testing the graphene-based membrane in water purification (see Table S1 for cost analysis).⁶ FIG. 8 (part b) demonstrates the new proposed mechanism of water permeation in CVD graphene film. Previous studies demonstrate water permeation through pores in CVD graphene which are generated post-growth in an energy-intensive, unscaleable process.^{2, 21, 22, 23} In contrast, the present invention demonstrates that few to multi-layer, nanocrystalline, CVD graphene films with overlapping grain boundaries which serve as effective water vapour permeation channels, enable robust anti-fouling desalination membrane. The membrane can simultaneously reject salt as well as damaging water born contaminants such as surfactants and oils.

### Structural Properties and Features of Permeable Graphene Film

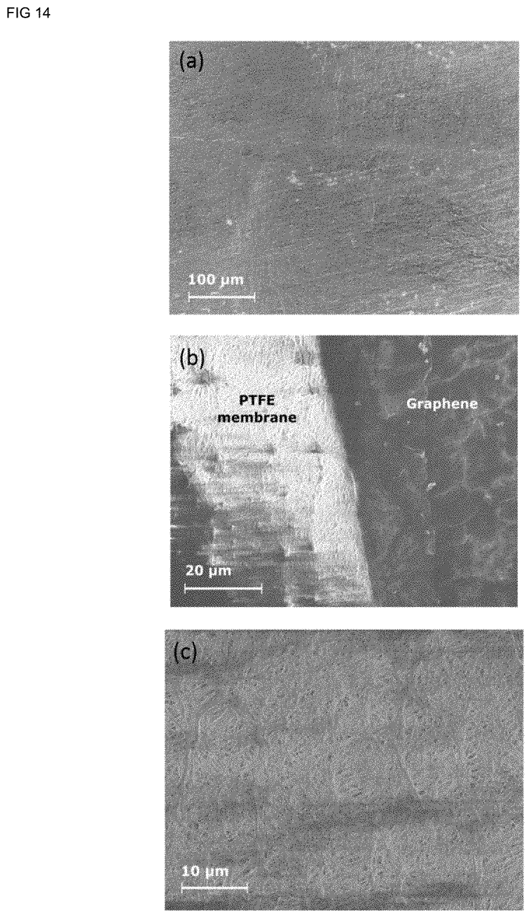

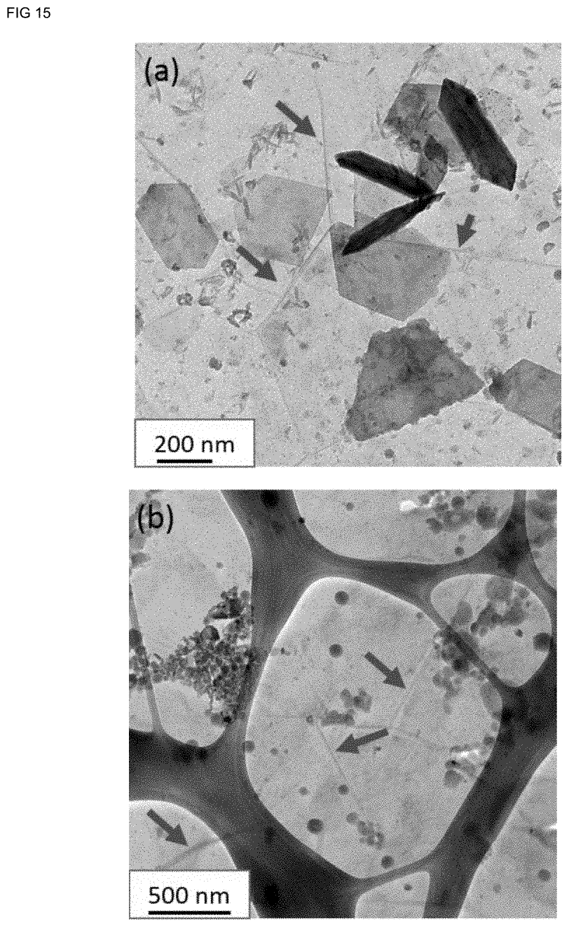

The morphology and structural properties of the graphene film was analysed by scanning electron microscopy (SEM) and transmission electron microscopy (TEM) (FIG. 9 and FIG. 14). The transferred graphene film homogeneously coated the PTFE membrane as is evident from SEM images taken at low- and high-magnifications (FIG. 9a-b). The graphene film is shown to conform to the membrane surface, as suggested by the visible wrinkles in the graphene film over the partially visible underlying membrane. Furthermore, the distribution of domain sizes, domain orientations, and thickness within the graphene film were characterized. A continuous few-layer graphene film with randomly oriented, overlapping stacked graphene layers, which often show hexagonal morphology indicative of single-crystallinity, was identified in low-magnification TEM (FIG. 9c). Bright-field (FIG. 9d) and dark-field (FIG. 9e) TEM imaging demonstrates that the base few-layer graphene is polycrystalline with misoriented domains, ranging from ˜200 nm to 600 nm, indicated by the variations in contrast at the domain boundaries and the presence of Moire fringes (periodic stripes) within the graphene domains. Importantly, a slight overlap of domain boundaries in multiple regions of the sample was observed—these serve as potential channels for the passage of water molecules (FIG. 15a-b).24 Based on TEM image contrast these channels are approximately 10 nm overlapping and extend along the length of the grain boundaries approximately 400 nm-1 μm. The channels height is the interlayer spacing of graphene, specifically, for turbostratic CVD graphene layers grown on nickel as in the present experiment, this value is 0.34 nm.²⁵ High-resolution TEM and selected area electron diffraction (SAED) analysis of these nanochannels is constrained due to the multilayer thickness and small channel width compared to selected area aperture size.

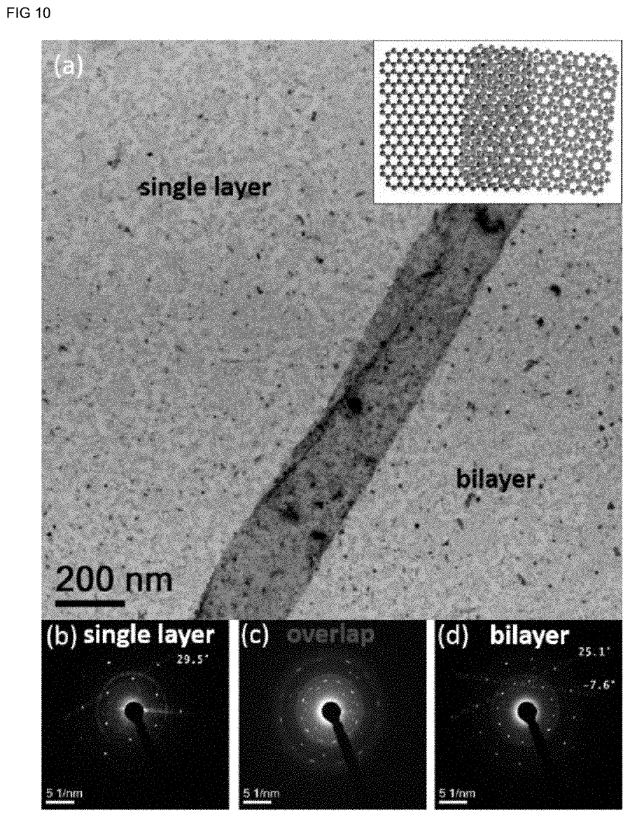

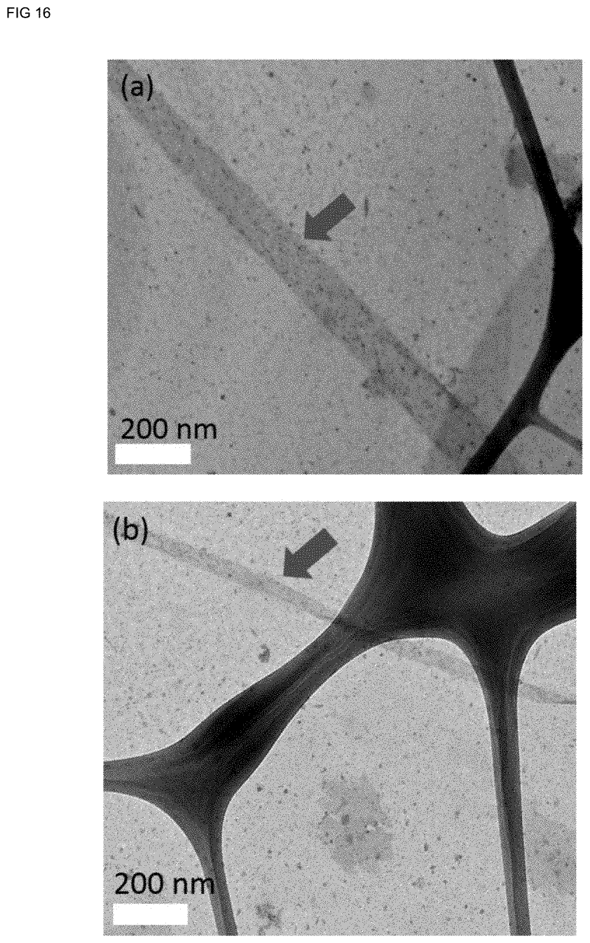

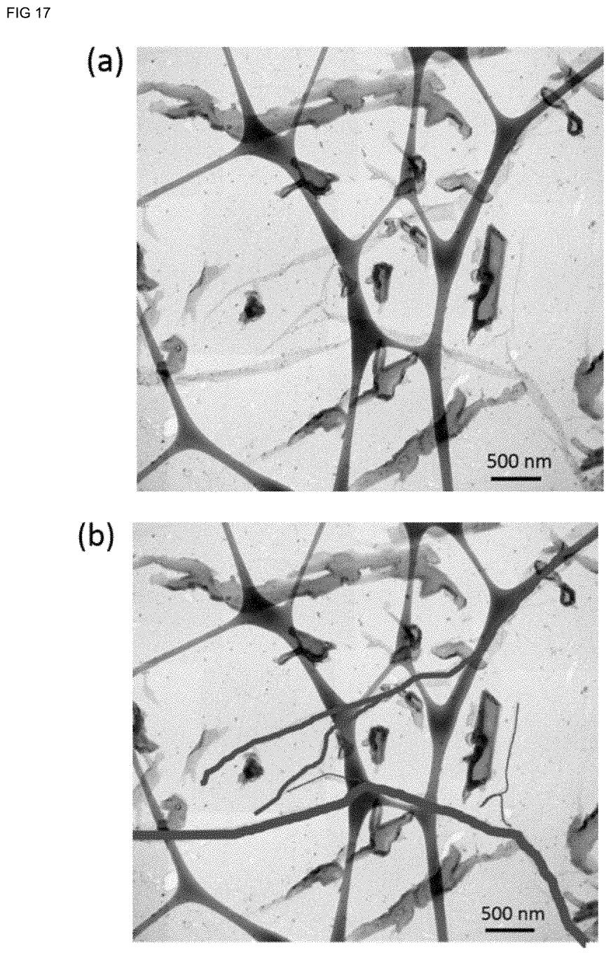

To provide conclusive evidence for the presence of the nanochannels in the permeable graphene, samples of predominately single or bilayer graphene with wider nanochannels were synthesised. Darker contrasted nanochannels with varying channel length >1 μm and varying channel width >100 nm are visible (FIG. 10a and FIG. 16, FIG. 17). SAED of the wider nanochannels is possible and confirms the presence of overlapping domain boundaries rather than folds or wrinkles of the graphene film. In particular, FIG. 10 demonstrates a ˜250 nm wide nanochannel formed over 2.5 μm length due to the mis-oriented overlap of single layer region (FIG. 10a left side) and a turbostratic bilayer region (FIG. 10a right side) regions. The darker contrast region is confirmed as an overlapping mis-oriented graphene domain boundary (or nanochannel) due to the single layer to bilayer transition and shift in the respective rotation axes on either side of the feature (29.5° on single layer side (FIG. 10b), and −7.6° and 25.1° on turbostratic bilayer side (FIG. 10d) (see inset of FIG. 10a for representative diagram showing relative rotations of domains). It is worth noting that while the existence of nanochannels could be confirmed using predominately single or bilayer graphene film grown from ambient air CVD process, however, these samples are fragile and inferior membranes compared to the few to multilayer graphene. The unique morphology of the ideal permeable few-layer graphene film, namely, high-density of sub-micrometre polycrystalline grains with numerous grain boundaries, as well as overlapping of mismatched graphene boundaries yielding nano-channels, will generate multiple passages for the efficient transport of water vapour.

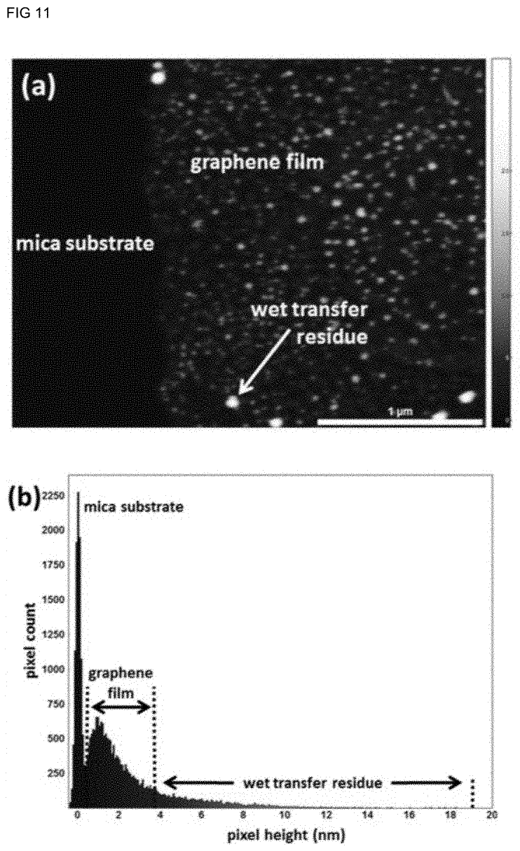

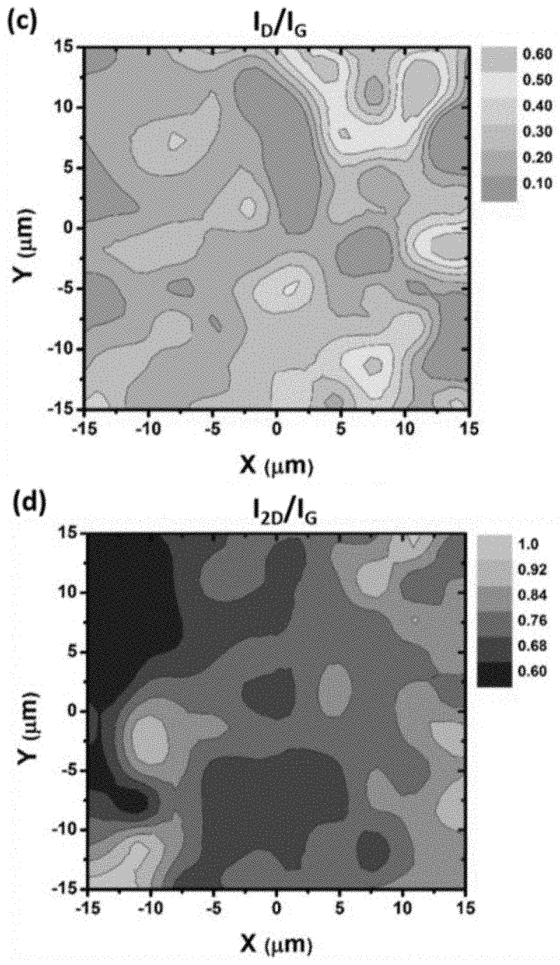

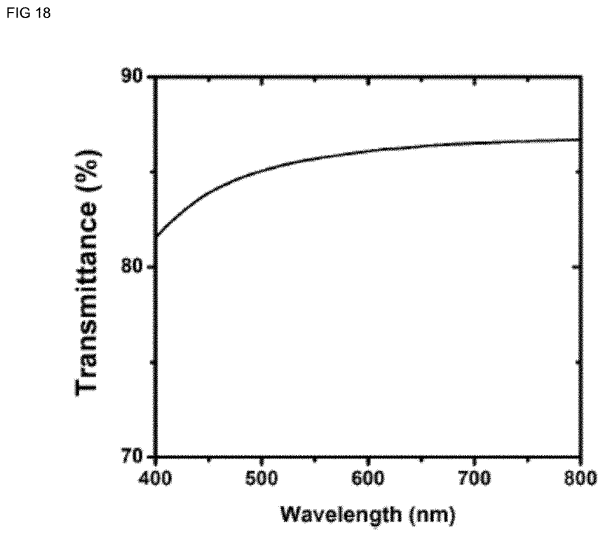

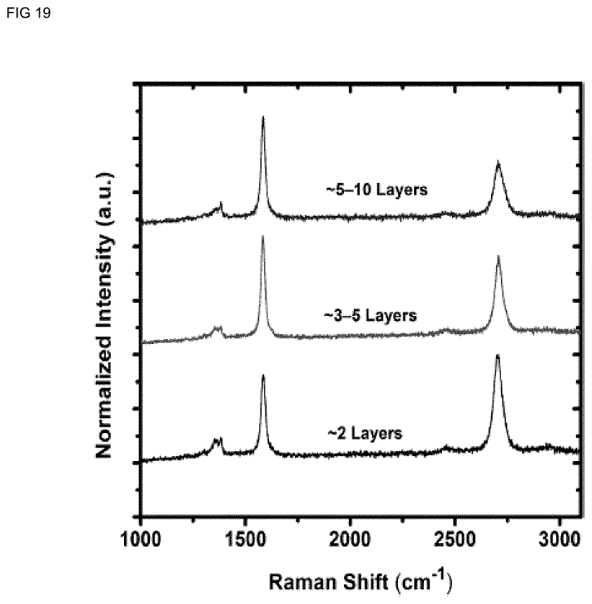

The structural properties of the graphene film were further examined by Raman spectroscopy mapping and atomic force microscopy (AFM) (FIG. 11). The multi-layer graphene film is observed to grow continuously over the entire surface, with regions of varying thickness. AFM topography imaging of the graphene film shows a thickness ranging from 0.7 nm to 3.7 nm (˜2 to 10 graphene layers), and a mean film thickness of 1.7 nm (FIG. 11a-b). The wet-transfer process likely gives rise to contaminants (e.g. PMMA residue and Fe particles) on the surface of graphene. Furthermore, transmittance of the graphene film is measured to examine the average film thickness. A transmittance of 85% at 550 nm is observed (FIG. 18). Raman characterization indicates that the graphene is a few-layer polycrystalline film. Raman spectral mapping of ID/IG and I2D/IG intensity ratios which shows defect distribution and relative thickness distribution of graphene film is conducted to determine the defect and the thickness uniformity in the films (FIG. 11c-d and FIG. 19). Three distinct peaks are present in the Raman spectra of graphene, namely, the characteristic disorder peak which arise from defects in the sp2 carbon (D-band) at ˜1350 cm-1, the graphitic peak which arise from the in-plane vibrational E2g mode of the sp2 carbon (G-band) at ˜1580 cm-1, and the second-order 2D-band which arise from three-dimensional inter-planar stacking of hexagonal carbon network at ˜2670 cm-1.26 The intensity ratios of ID/IG is 0.1-0.3 and that of I2D/IG is 0.6-1 (FIG. 11c-d). This disorder content may be attributed to defects, which arise from grain boundary interactions by analysing the G peak. The 12D/IG intensity ratio suggest that the film is composed of few-layer graphene, with variations in film thickness from 2 to 10 atomic layers. These characterizations are in a good agreement with the structure of the graphene film determined by TEM and other characterizations.

Graphene-Based Membranes for Water Desalination with Fouling Contaminants and Desalination of Seawater from Sydney Harbour

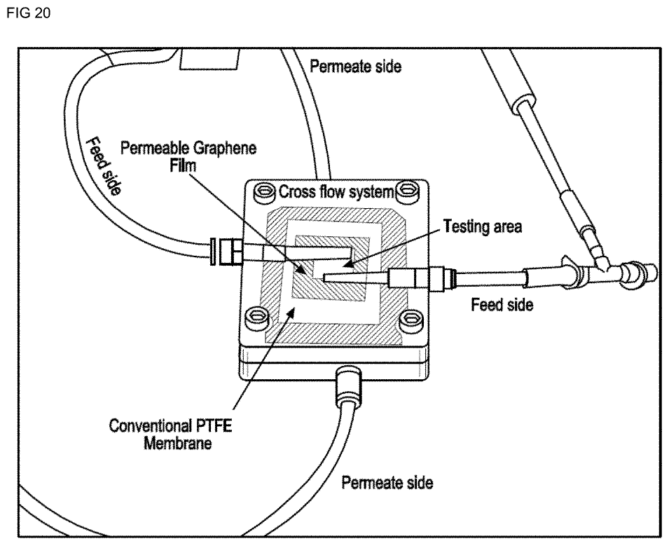

The performance of the permeable graphene based (graphene/PTFE based MD membrane) membrane was carried out by direct contact MD (DCMD) using a range of solution mixtures containing, highly saline solutions with the presence of surfactants, mineral oil, and real seawater collected from Sydney Harbour. The water vapour flux and salt rejection were measured to characterize the purification of water by the graphene membrane. Performance of the permeable graphene based membrane is benchmarked against the commercial PTFE MD membrane (Ningbo Changqi, 120 μm thickness, 0.4 μm pore size). The testing is carried out in a continuous, co-current cross flow system illustrated in FIG. 20.

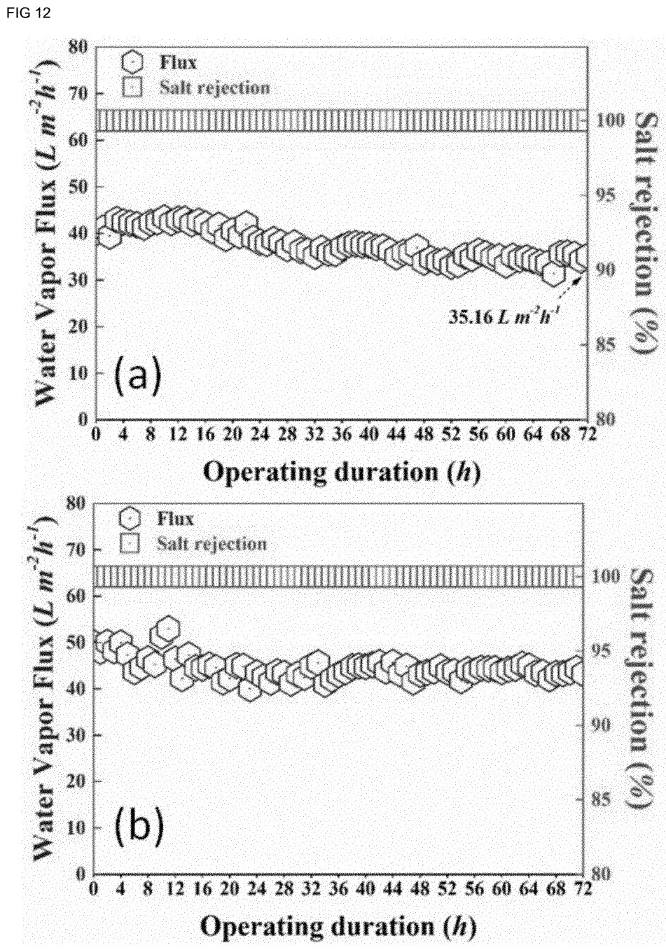

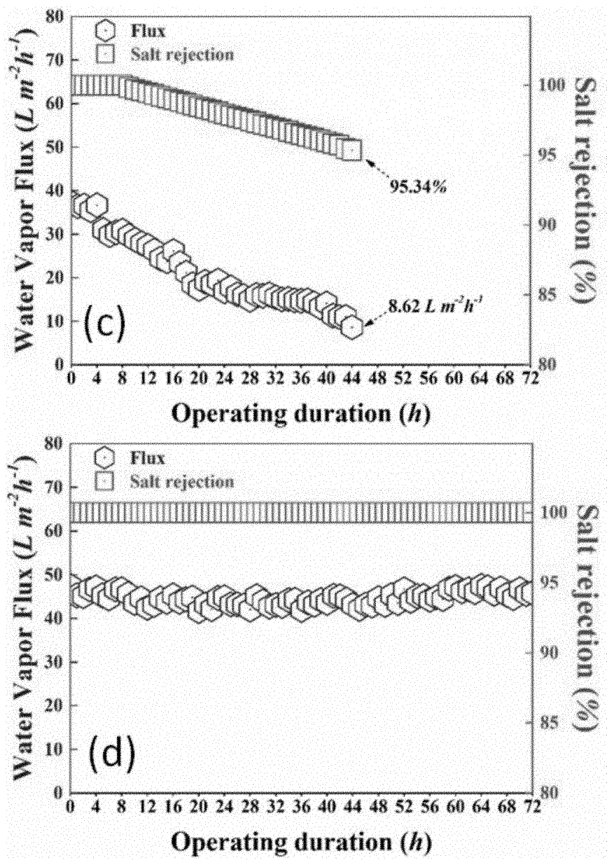

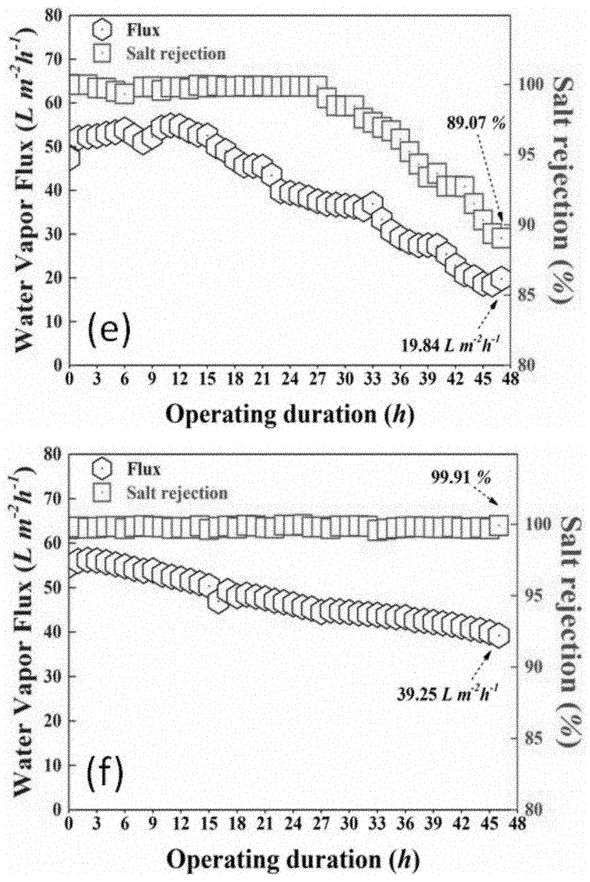

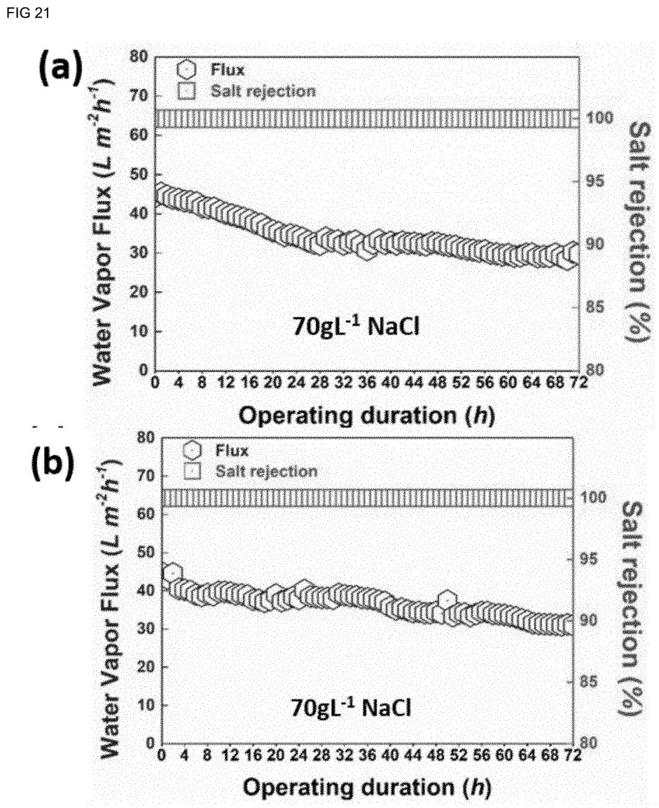

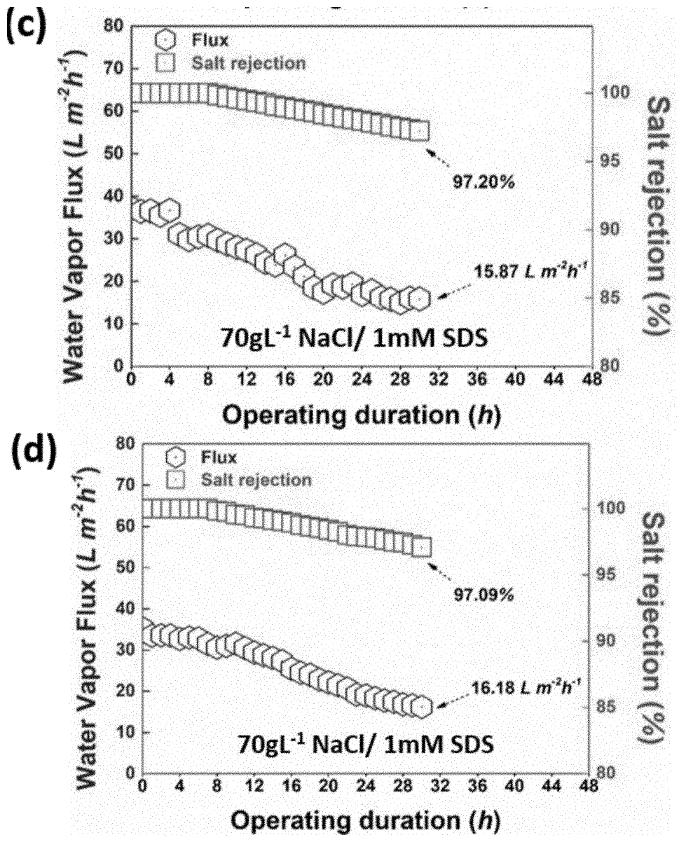

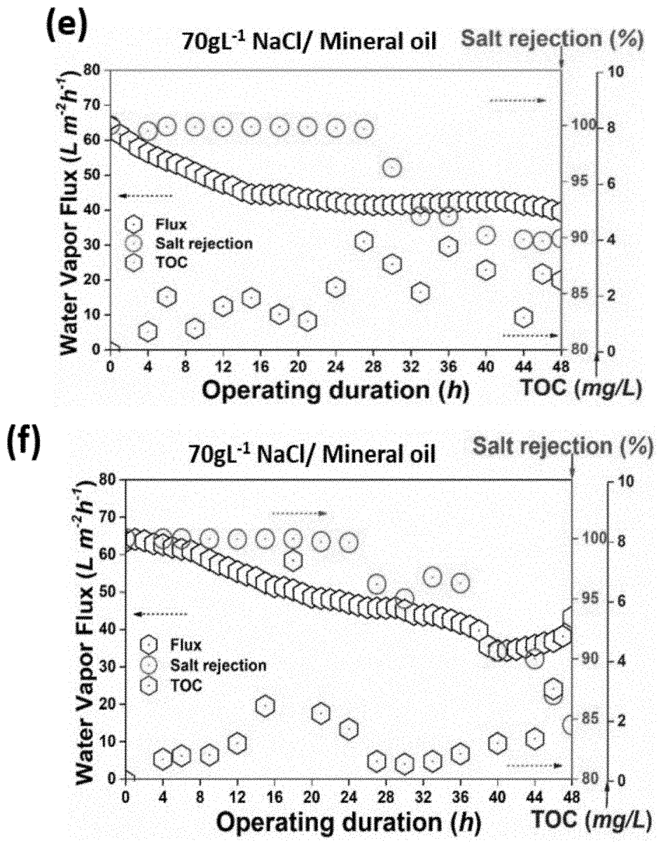

With NaCl feed solution (70 gL-1 NaCl, typical concentration of brine water), both the permeable graphene based membrane and commercial PTFE membranes exhibit similar salt rejection, 99.9% after 72 hours of operation. A relatively higher water vapour flux was observed for the permeable graphene based membrane in comparison with the pristine PTFE based MD membrane (FIG. 12a-b). Moreover, to explore the water vapor permeation governing factors in permeable graphene based membrane, the membrane was tested under different cross flow rate of the water streams and under different temperature gradient created by increasing the temperature of the feed water (FIG. 21). The result shows that as the cross flow rate of the water streams increased, a systematic increase in the water vapor flux (FIG. 21a) was observed. Similarly, as the temperature gradient increase, a systematic increase in the water vapor flux (FIG. 21b) was observed, revealing both the cross flow rate of the water and the temperature gradient are important factors in controlling the water vapor permeation via permeable graphene. Furthermore, in both cases, at different cross flows and under different temperature gradients, permeable graphene based membrane exhibited stable water vapor flux over the total duration of MD operations.

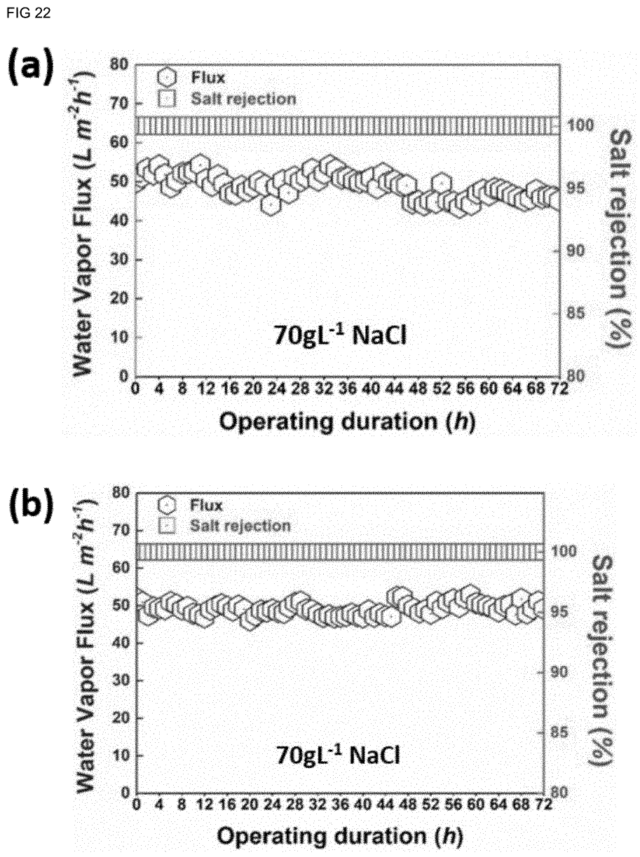

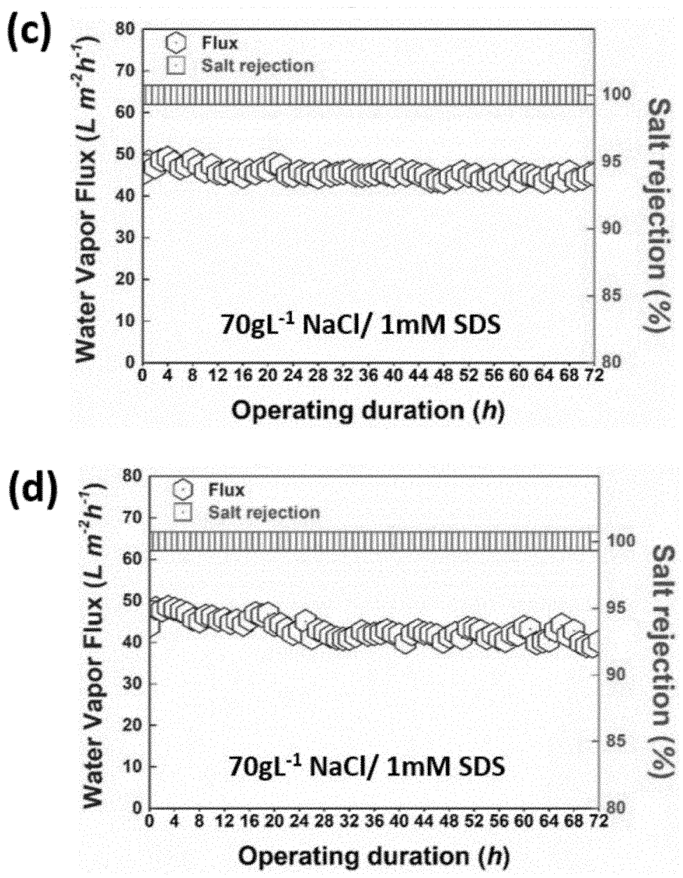

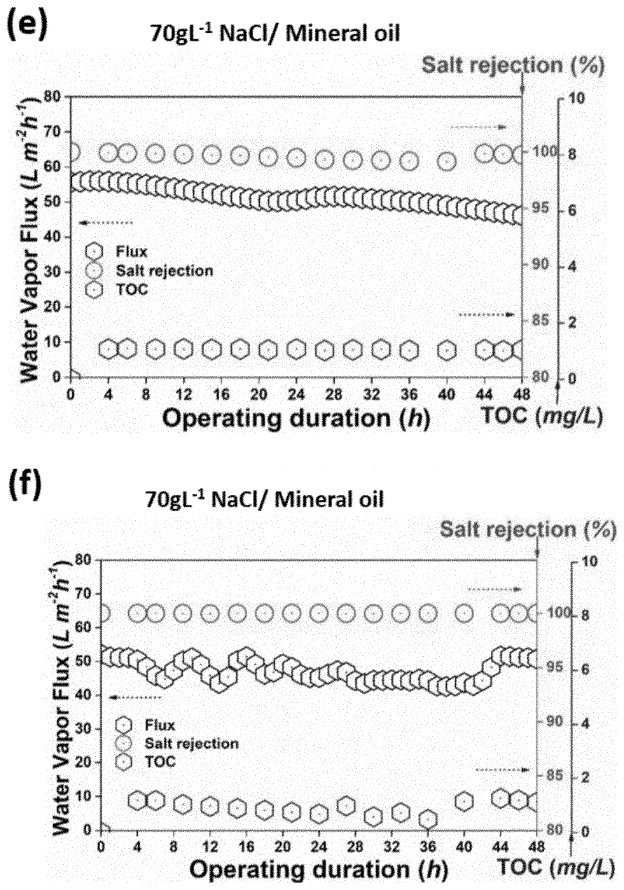

In MD separation process, liquids with low surface tension (i.e., saline solution with surfactant such as sodium dodecyl sulfate (SDS)) causes detrimental pore fouling and/or wetting in MD membranes which leads to significant degradation in membrane performance (see FIG. 22)27, 28. Therefore, to explore permeable graphene based membrane's capability under such mixture of solutions containing detrimental foulant, both pristine PTFE membrane and permeable graphene based membrane were tested under saline solution containing surfactant such as SDS. Significant fouling is evident for the pristine PTFE based MD membrane processing saline/SDS feed solution (70 gL⁻¹ NaCl with 1 mM SDS) with a drop in water flux from 40 Lm⁻²h⁻¹ to 8 Lm⁻²h⁻¹ over 44 hours (FIG. 5c). In addition, a notable degradation in salt rejection is observed from 100% to 95%. In contrast, the permeable graphene based membrane demonstrated stable and high water vapour flux (50 Lm⁻²h⁻¹) and stable salt rejection (100%) over 72 hrs of MD operation under similar operation conditions (FIG. 12d).

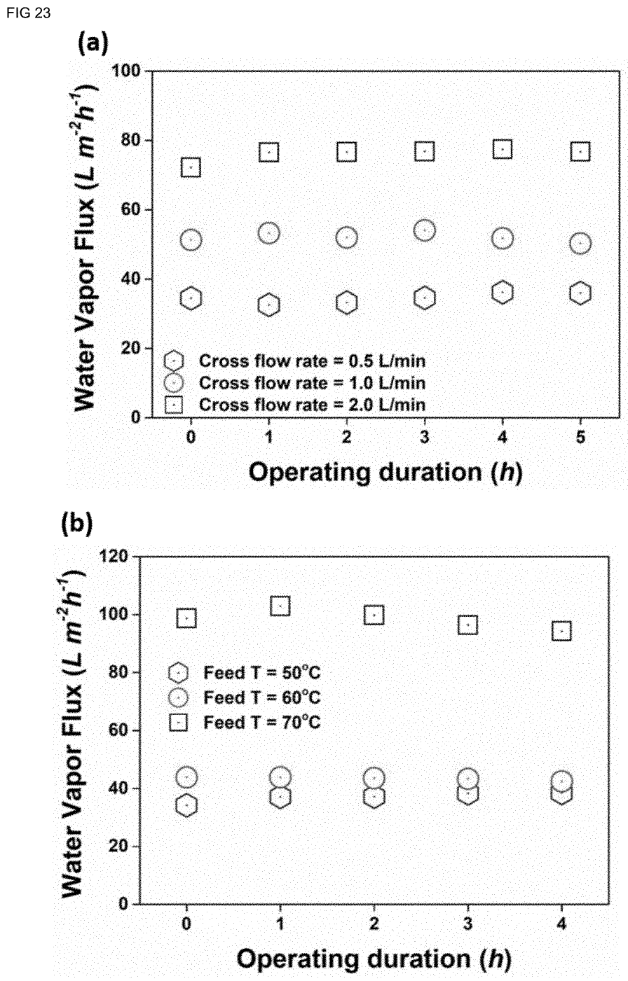

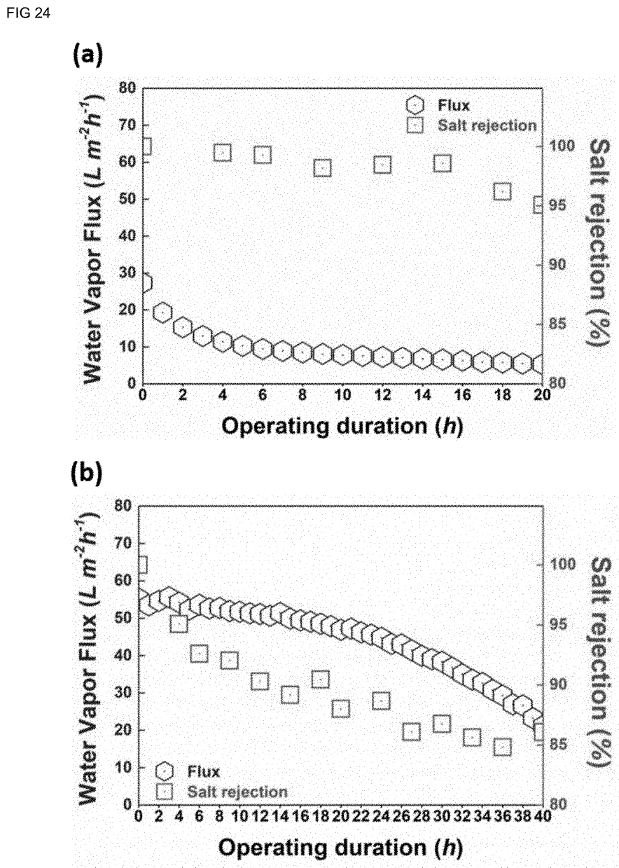

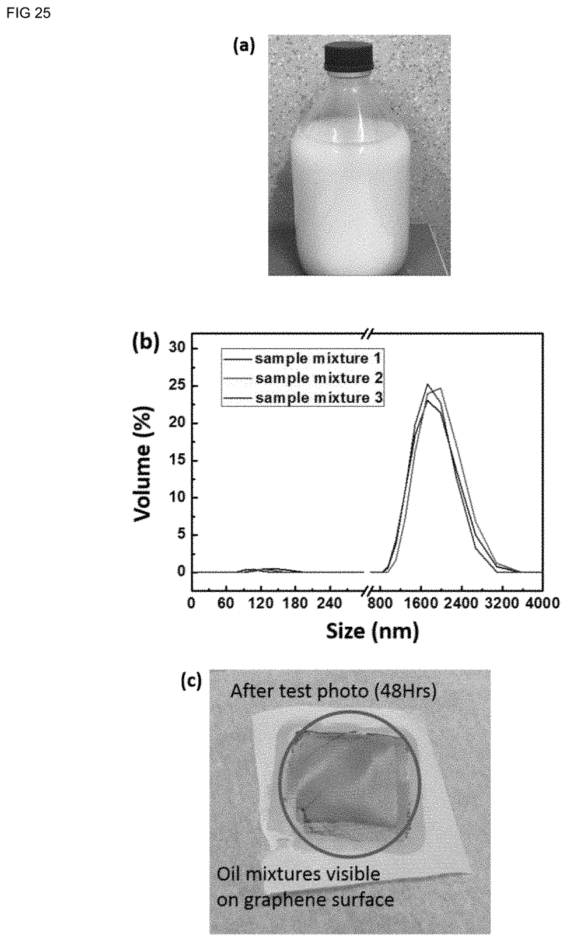

The permeable graphene based membrane was also tested with the inclusion of high concentration of oil compounds—another common contaminant which causes significant wetting and fouling problems in widely used MD membranes such as commercially available PTFE and PVDF based MD membranes (FIG. 12e-f and see FIG. 22). Substantial fouling is evident for the pristine PTFE based MD membrane when processing the saline water/mineral oil (see FIG. 23a-b for the emulsion mixtures used for experiment and its oil size distribution and FIG. 34) feed solution (1 gL-1 mineral oil with 70 gL⁻¹ of NaCl and 1 mM NaHCO₃) (FIG. 12). This is indicated by a rapid degradation of water flux from 50 Lm⁻²h⁻¹ to 19 Lm⁻²h⁻¹, and a significant reduction in the membrane's salt rejection capacity from 100% to 89% over 48 hours. In contrast, the permeable graphene based membrane outperformed the commercial PTFE based MD membrane, demonstrating a significant improvement in the salt rejection (100% to 99.9%) and retention of water vapour flux (52 Lm⁻²h⁻¹ to 39 Lm⁻²h⁻¹) for the 48 hours of MD operation under similar conditions (FIG. 12). Though significant quantities of oil were visible on the graphene surface after the MD operation, the present results indicate that wetting or fouling of the membrane surface was insignificant in the permeable graphene based membrane, unlike the commercial PTFE based MD membrane case. All the experiments were repeated to demonstrate the reproducible performance of the present membrane. During repeat experiments, the total organic carbon (TOC) level in the permeated water streams was monitored (to examine oil rejection) over 48 hours (see FIG. 22e-f). The result shows a stable organic carbon rejection over 48 hours of MD operation was achieved, revealing stable oil rejection via permeable graphene based membrane. Furthermore, all the repeat experiments reveal that the present permeable graphene based membrane exhibited reproducible, stable, anti-fouling nature with excellent salt and oil rejections under saline water and saline waters with membrane fouling contaminants such as surfactants and oils. Overall, the present MD demonstration using permeable graphene demonstrated the potential to enable the expensive, multi-stage pre-treatment free, direct membrane based water purification of liquids containing mixtures of damaging water born contaminants where conventional membrane fails to deliver.

Desalination of Seawater from Sydney Harbour Using Permeable Graphene-Based Membrane

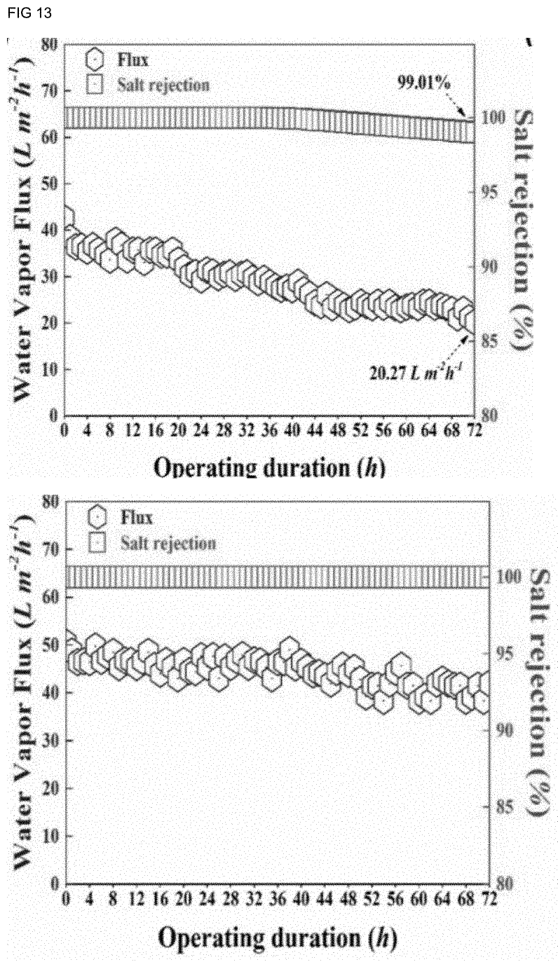

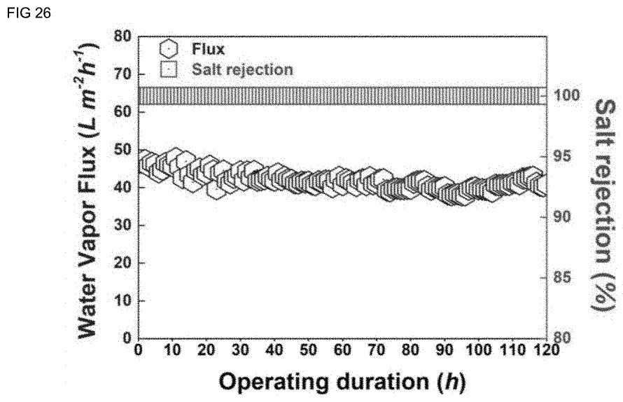

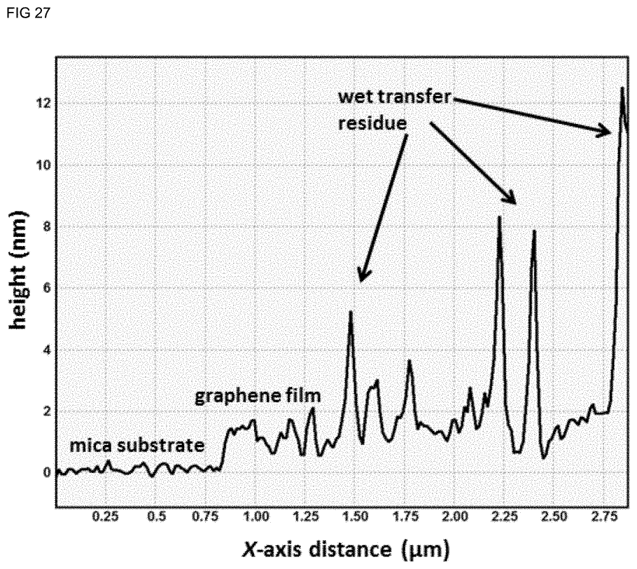

To demonstrate the practical applicability of permeable graphene based membrane in real desalination situation, water desalination tests with unprocessed real seawater feed (total dissolved solids of 34.2 gL⁻¹) (FIG. 13) were carried out. Real seawater was collected from the Sydney Harbour, NSW, Australia (see Table S3 for analysis of the sea-water). The seawater collection site is central to an environment of households and ongoing industrial activities. The results show, the commercial PTFE based MD membrane fouled while processing unprocessed seawater with a continuous reduction in water vapour flux (40 Lm⁻²h⁻¹ to 20 Lm⁻²h⁻¹) over 72 hours, and a slight decrease in salt rejection (100% to 99%) (FIG. 13). Conversely, the permeable graphene based membrane exhibited superior performance in salt rejection (100%), while maintaining a high water vapour flux (50 Lm⁻²h⁻¹ to 46 Lm⁻²h⁻¹) and long term stability over 72 hours, in the desalination of real seawater processing 0.4˜0.5 L of seawater per day over 4 cm2 of permeable graphene based membrane. Moreover, to demonstrate the permeable graphene based membrane's long term stability under real sea water feed, the membrane performance for prolonged duration (120 hours) of MD operation (see FIG. 26) was tested. The result shows, over 120 hours of MD operation, a stable water vapor flux with excellent salt rejection of 99.99% was observed, demonstrating permeable graphene based membrane's excellent long term stability. Furthermore, concentration polarization effect was insignificant for the permeable graphene based membrane even at the prolonged operation of MD with real sea-water which have multitudes of components. Overall, the present results demonstrate that the ambient-air-derived CVD graphene films of the present invention are promising active materials for MD and demonstrate promising applications where hydrophobic CVD graphene film can be applied in water purification. Moreover, the present work demonstrates a synergistic effect of applying a new 2D nanomaterial in solving key problems in membrane water purification.

The membranes of the present invention exhibited a relatively high water vapour flux through the graphene membrane as compared to the commercial PTFE based MD membrane. This indicates the presence of numerous potential regions in the graphene film which allow water vapour to be transported with a fast flow. Unlike the previous studies where post-treatment techniques create nanopores in the graphene surface, the present inventors did not observe nanopores, in the traditional sense, in the present few-layer graphene microstructures. Rather a multi-layer graphene film with numerous graphene grain boundaries arising from the small domain sizes and numerous overlapping regions of adjacent graphene grains with the mismatched graphene grain boundaries was observed.

These nanochannels created by mismatched and overlapping graphene domains appear to facilitate the fast transport of water vapour.³⁰ The possibility of water molecule transport through such overlapping graphene domains is confirmed using MDS, and this further validates the observed effective water transport through the graphene-based membrane. Recently, another advantageous merit of using graphene in water transport has been demonstrated that minimal resistance occurs when water or water vapour is transported between graphene sheets.³¹ Moreover, multiple characterizations (i.e., AFM, SEM, and TEM), shows that the porous graphene film of the present invention had variations in the number of layers over microscopic regions induced by mis-oriented, overlapping, and sub-micron-sized grains. Recent studies show such structural properties promote deformations (i.e., wrinkling) in graphene³² Such nanoscopic wrinkling would increase the surface roughness of the porous graphene film of the present invention and create ideal surface structures (i.e., nanoscopic bottleneck sites) to promote the water vapour entry and rapid permeance.

### Thermal Insulation Effect by Permeable Graphene and Mechanical Strength of the Permeable Graphene Based Membrane

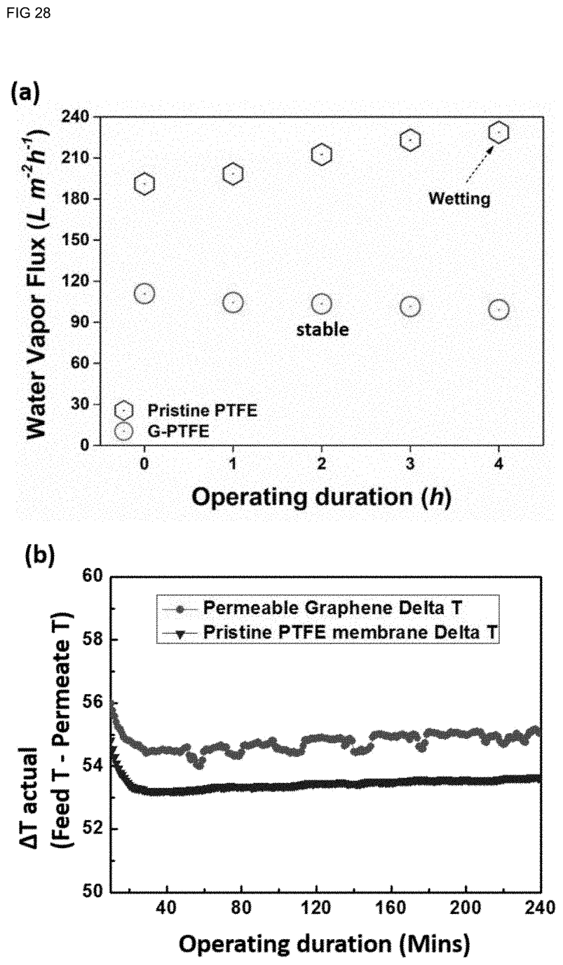

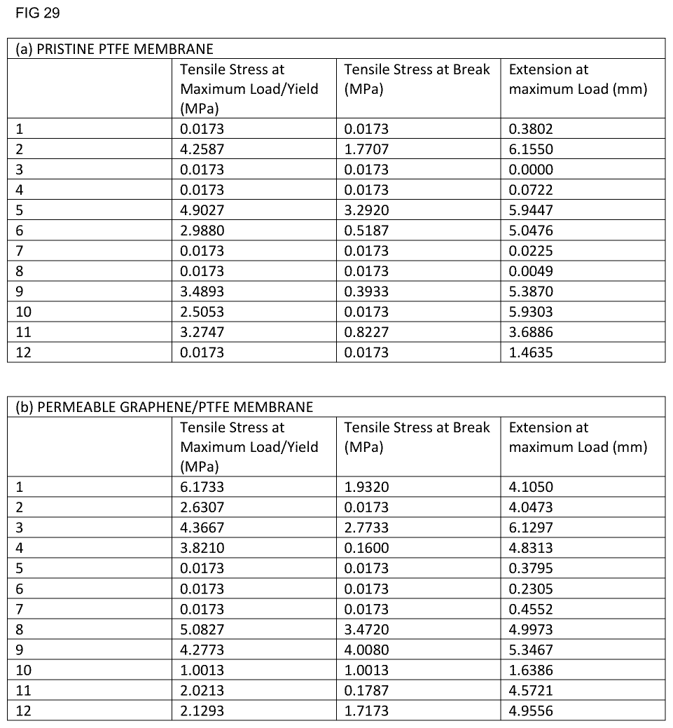

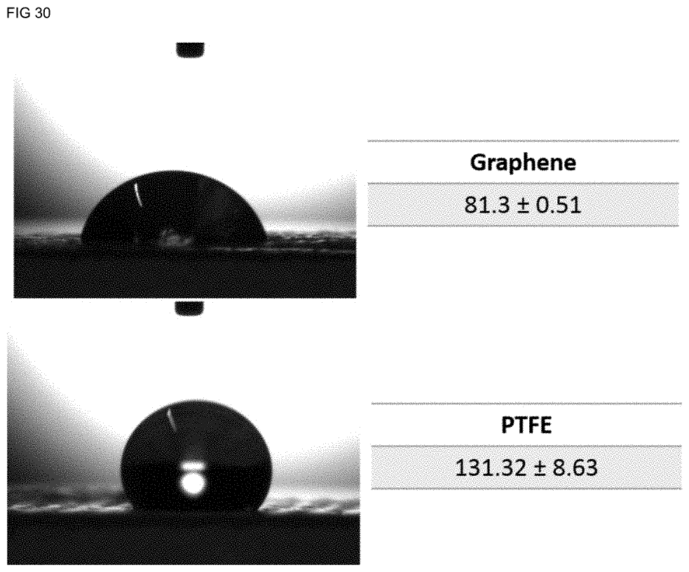

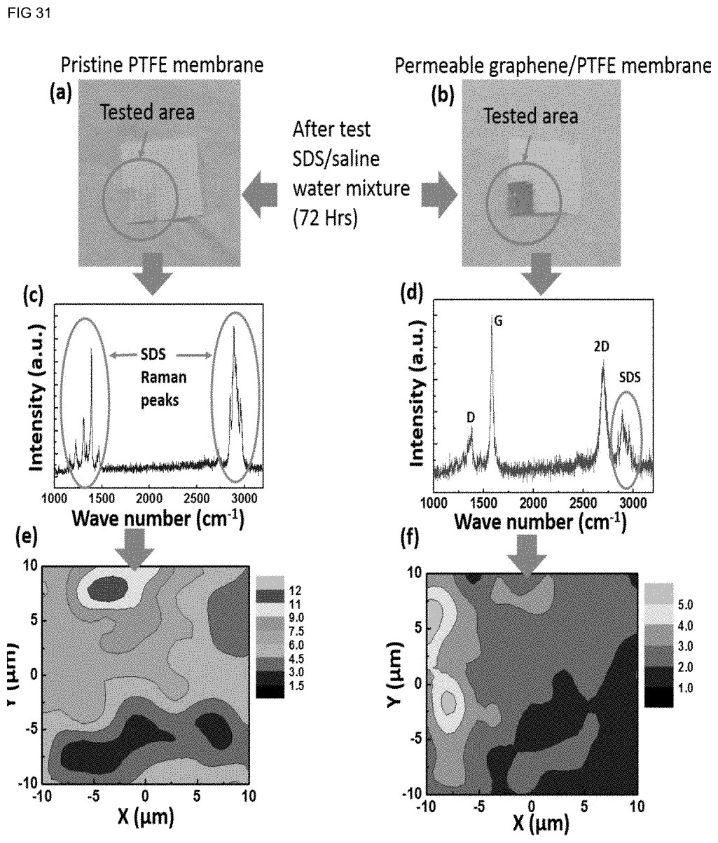

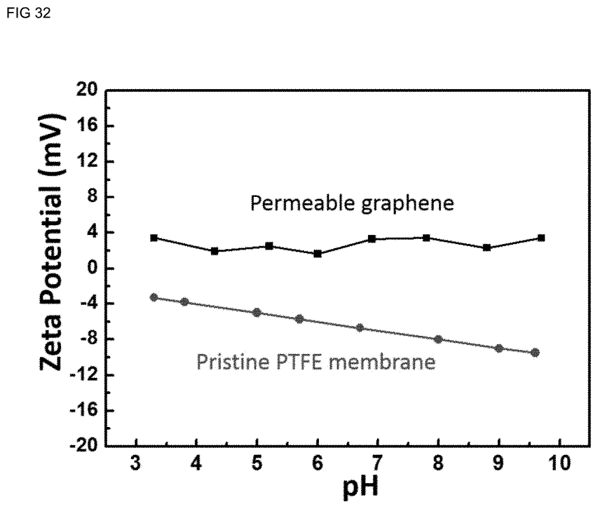

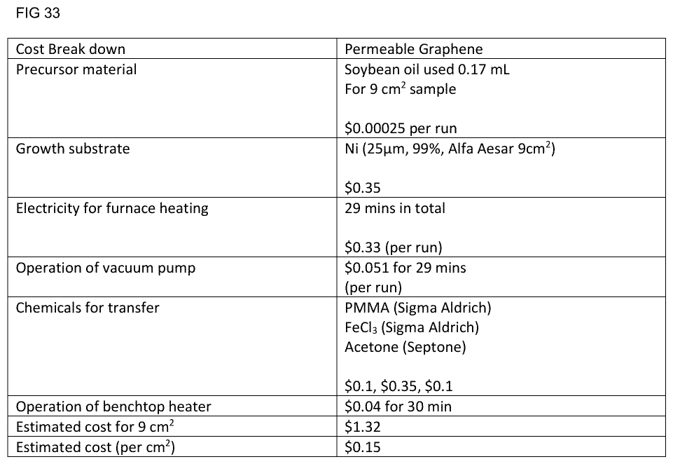

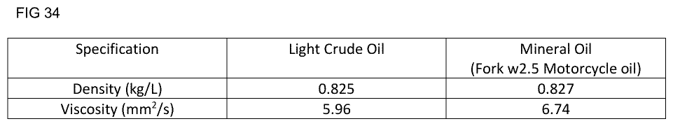

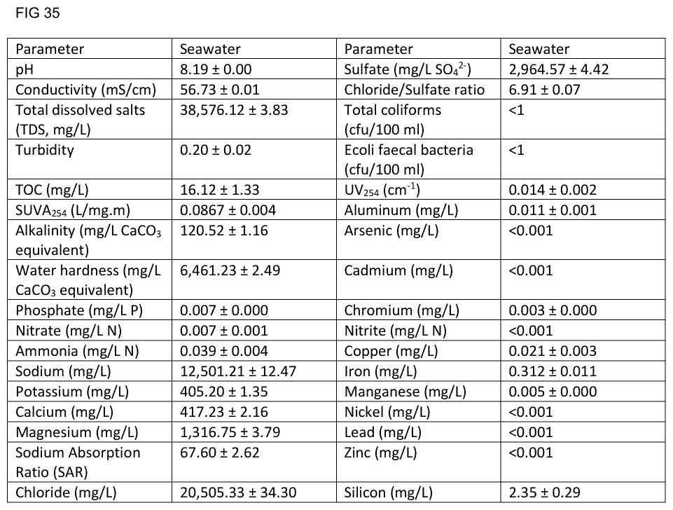

Another important aspect which needs to be considered in membrane distillation is heat conduction. A major drawbacks of conventional MD membrane is its inability to provide thermal insulation across the membrane between hot feed and cold permeate side.¹³ Continuous loss of heat through membrane leads to low water vapour flux and reduction in water vapour flux over long operation time which was one of an unsolved problem in MD membrane.^{16, 17, 33} Graphene is a two dimensional nanomaterial with high anisotropy in thermal conductivity, where high thermal conductivity is observed in X-Y direction due to sp2 bonding in graphene lattice and poor thermal conduction in Z directions arising from weak van der Waals interaction which is a favourable feature for MD applicaiton.^{16, 17, 34, 35} To explore the thermal benefits of incorporating a permeable graphene film in the membrane distillation membrane, an experiment to measure the water flux and the temperature at the feed side of a membrane and the permeated vapor temperature to calculate the actual temperature difference under high temperature gradients (ΔT=70° C.) was carried out, to clearly see the thermal insulation effect in small membrane area and it was compared to the pristine PTFE MD membrane (FIG. 28). As expected, high feed water temperature created lower liquid entrance pressure which caused membrane deterioration in commercial PTFE MD membrane as water vapor flux increased rapidly over short duration of MD process. While permeable graphene based membrane exhibited stable water vapor flux even at the high temperature of feed water (FIG. 28a).

More importantly, permeable graphene based membranes were able to maintain stable and higher actual temperature gradient compared to pristine PTFE membrane (FIG. 28b), providing experimental evidence of thermal insulation effect of the permeable graphene film and also demonstrating potential to increase the stable operation temperature window of the MD process using permeable graphene.

Another important characteristic of the membrane is its mechanical strength. The permeable membranes of the present invention show a marginal improvement in mechanical strength after the incorporation of permeable graphene compared to pristine PTFE membrane (FIG. 29).

### Anti-Fouling Properties of Graphene Membranes

Surface energy plays a critical role in anti-fouling and anti-wetting properties of the MD membrane with an ideal MD membrane being highly hydrophobic (i.e., high water contact angle). While the graphene-based membranes of the present invention are mildly hydrophobic (with a contact angle of 81.3°), they exhibit significantly superior anti-fouling and anti-wetting capabilities compared to the highly hydrophobic surface of commercial PTFE based MD membranes (contact angle of 131.3°). (FIG. 30) There are thus additional factors which would prevent the contaminant molecules from blocking or adhering to water vapour channels. To better understand the anti-fouling nature of the permeable graphene film of the present invention, an adsorption energy simulation was carried out to investigate the interaction between contamination particles such as SDS with nano-channels at grain boundaries. The calculations show the adsorption energy, Ead, of one SDS molecule on the grain boundary is −2.36 eV and the adsorption energy of H₂O is −0.12 eV, which indicates the interaction between graphene and the contaminant molecules are weak physisorption. Similar adsorption energy is expected for molecules with similar chemical structure as SDS (e.g. mineral oil). Moreover, weak physisorption of contaminants on graphene surface is overcome due to the kinetic energy provided by continuous feedwater flow.

To experimentally verify weak physisorption behaviour between SDS and the present graphene surface, the experiments were repeated with pristine PTFE membrane and the permeable graphene based membrane with SDS/saline water mixtures for 72 hours, then samples were dried without any cleaning process and analysed using Raman spectroscopy. Knowing that SDS has clear and distinct Raman peaks, areal mapping of SDS Raman intensities was carried out to find out relative differences in SDS adsorption on pristine PTFE membrane and permeable graphene surfaces (FIG. 31). The results show significantly lower SDS Raman intensities were observed for permeable graphene surface, experimentally revealing weaker interaction between graphene surface and SDS compared to pristine PTFE membrane, reinforcing the adsorption energy simulation.

While the presence of polycrystalline, mismatched graphene domains and grain boundaries is disadvantageous in some graphene applications (i.e., high speed electronic devices, etc.), the present results suggest that such morphology is favourable for water purification applications and provides key advantages in facilitating the rapid permeation of water vapour and its effective rejection of contaminants.

Thus, without any post-synthesis pore engineering, the permeable membranes of the present invention demonstrate high-water flux (˜50 Lm⁻²h⁻¹ for 4 cm², up to ˜0.5 L per day) excellent salt rejection (99.9%) when processing highly saline water (i.e., NaCl of 70 gL⁻¹), and exceptional anti-fouling properties by rejecting common water borne contaminants.

### Performance Under Extreme pH and Saline Conditions

Water treatment is an important part of many different industries including mining, agriculture and material processing. Water from these sources is processed in a number of different steps but they invariably involve a reverse osmosis step at some point. This step is vital in removing dissolved salts from solution. Typical RO membrane specifications require a flow of 44.6 L·m⁻²·h⁻¹ with 99.5% rejection, at 1551 kPa of applied pressure and a feed NaCl concentration of 0.034 M. Before the RO step, the water must be processed to ensure that the membrane does not foul due to the presence of organic or other contaminants. Even once potential foulants have been removed, problems still remain when extreme pH solutions or salinity is present.

Membrane distillation, as an alternative to RO, requires no pressure gradient but instead a relies upon a temperature gradient to produce a water flux. This temperature gradient can be created using waste heat sources. MD processes maintain flux even as the filtrate salt concentration varies however fluxes are not as high as RO and the process is still considered to be in its infancy. Furthermore, MD also suffers from fouling and pH issues. Operation of membranes in extreme pHs is difficult and the process is significantly less effective under these conditions relative to neutral conditions. Composite polyamine membranes have been used at pHs of 1 and 13. The best flux achieved was 16 L·m⁻²·h⁻¹, the rejection of NaCl was up to 85%, from a feed of 0.034M NaCl in an RO mode at 1000 kPa.

To improve the performance of membranes operating in a variety of modes, 2D materials have been tested. Graphene-based membranes in osmosis processes have been shown to be capable of rejecting numerous salts in solution. Graphene oxide and graphene powders has been successfully incorporated into a membrane, the best reported performance was in forward osmosis mode, 97% NaCl rejection using a 7500 kPa osmostic pressure the flux of water was 0.5 L·m-2·h-1 with a feed NaCl concentration of 0.1 M. Chemical vapour deposition grown graphene, with post growth pore generation, has also been explored as a membrane material. Rejection of sub-nanometre radius hydrated ions remains elusive, the best performing membrane achieves a minimum 90% rejection for hydrated ions with radii larger than 0.9 nm³. No CVD grown 2D material with or without modification has been shown to be an effective membrane operating in MD mode. There is to the present Applicant's knowledge no graphene based membrane that has shown to operate in harsh conditions. Furthermore, currently there is no membrane capable of withstanding harsh conditions and maintaining performance, water flux and salt rejection level, an industrially applicable amount of time.

The permeable nanochannel graphene is prepared in accordance with the method of the present invention is wet-transferred (such as via a PMMA-assisted wet-transfer process) to a widely used MD membrane such as Polyvinylidene fluoride (PVDF) and Polytetrafluoroethylene (PTFE) MD membranes.

Utilization of binder material such as PMMA enabled permeable graphene to be used in other membrane substrates which are not chemically resistant such as PVDF membrane, where removal of binders from permeable graphene restricted its range of supporting membrane which could be used.

It has surprisingly been found that permeable nanochannel graphene on PTFE supporting membrane is an effective purification membrane for extreme pH water which not only rejects solvated salt ions but also reject H₃O⁺ and OH⁻ solvated ions which allow us to obtain neutral pH water as a permeates regardless of the extreme pH range of feed waters.

In addition, a similar membrane using PMMA binder/graphene on a less chemically resistant PVDF supporting membrane resulted in protection of the supporting membrane by the chemically robust permeable graphene.

Surface features of the permeable nanochannel graphene film of the present invention were analysed by scanning electron microscopy (SEM). Transferred permeable graphene film was seen by both low- and high-magnification SEM to be uniformly coated on the supporting PTFE membrane. High magnification SEM images reveals small nanometer scale graphene domains with graphene grain boundaries.

The graphene film used had low thickness variation, low-defect, good structural quality, multi-layer graphene film with polycrystalline graphene domains

TEM and scanning TEM (STEM) analysis of the permeable graphene film sample after filtration test provided further evidence to its excellent capability as an effective purification membrane. The used graphene membranes contained a very low quantity of salt residues, which suggests an antifouling nature. For the minimal salt residues that are present these can be nanoparticles or non-uniform surface deposits. In rare instances the salt residues accumulate along the length of the overlapping domains which demonstrates that the mechanism of water transport is through the permeable nanochannels of graphene membrane.

### Comparison of Membrane Performance of PTFE MD Membrane and Permeable Graphene/PTFE Membranes for Purification of Extreme pH Waters.

To demonstrate the capability of permeable graphene in purifying water mixture of extreme pH waters with solvated salts ions, range of solution mixture containing saline solution (35 gL⁻¹) with 0.1 M of sulfuric acid and saline solution (35 gL⁻¹) with 0.1 M sodium hydroxide was prepared. The pH of the feed water was adjusted to pH 2 for acidic and pH 13 for basic feed water by adjusting the amount of sulfuric acid and sodium hydroxide solution. Then the permeable graphene/PTFE MD membrane test was carried out by direct contact MD. The water vapour flux, salt rejection and pH were continuously monitored over 72 hours of testing period. Similarly, performance of the pristine PTFE MD membrane test was performed for the comparison.

Membrane test with acidic feed solution (35 gL⁻¹ NaCl/0.1M H₂SO₄, pH2) shows that the chemically resistant pristine PTFE membrane retained its structural integrity and mechanical stability after 72 hours of testing. However, a gradual decrease in pH was observed over 72 hours reaching pH of 6.0 at the end of 72 hours with decreasing in salt rejection. More importantly, membrane fouling was evident as there was a continual decrease in water vapour flux from 23 Lm⁻²h⁻¹ to 17 Lm⁻²h⁻¹ over 72 hours. After 72 hours testing, SEM analysis of the PTFE membrane showed partial pore blocking of the membrane. Moreover, after testing photo the membrane also showed signs of potential damage or surface property changes relative to the pristine PTFE membrane. The membrane which was in contact with the acidic feed solution exhibited a deep black colour at the end of the 72 hours of testing. However, when permeable graphene was incorporated on the PTFE membrane, a stable neutral pH permeate was retained and a stable salt rejection of 99.9% and stable water flux of 25 Lm⁻²h⁻¹ was observed for 72 hours of operation. This demonstrated that the membranes of the present invention had an anti-fouling nature, excellent salt rejection capability and excellent H₃O⁺ rejection capabilities. When membranes were tested with basic feed solution (35 gL⁻¹ NaCl/0.1M NaOH, pH13), pristine PTFE membrane exhibited an increase in pH, reaching pH of 7.5 at the end of 72 hours with decreasing in salt rejection from 99.9 to 97%. In the case of a basic solution, membrane performance started to sharply decrease from around the 48-hour mark unlike the case of an acidic solution which exhibited a gradual decrease in membrane performance. More importantly, membrane fouling was more significant in the case of a basic solution, as evident from flux curve, where a continual decline in water vapour flux was observed from 23 Lm⁻²h⁻¹ to 12 Lm⁻²h⁻¹ over 72 hours. Post-test SEM analysis of the PTFE membrane shows significant pore blocking of the membrane after 72 hours. Like the acidic feed water experiment, membrane also shows signs of potential damage to the original pristine PTFE membrane in terms of reduced physical stability and discoloration of the membrane. However, when permeable graphene film was incorporated on to PTFE membrane, a stable neutral pH, an excellent and stable salt rejection of 99.9% and stable water flux of 25 Lm-2h-1 was observed for 72 hours of operation. The nanochannel graphene membranes of the present invention showed an excellent anti-fouling nature, salt rejection capability and OH⁻ rejection capability unlike the unmodified PTFE membrane. The nanochannel graphene membrane showed good structural integrity after 144 hours of testing, (72 hours acidic filtration, followed by 12 hours of cleaning, followed by 72 hours basic solution) with a large amount of salt accumulation on the surface of graphene. Overall, in the case of water mixtures with extreme pHs (pH2 and pH13), even the purification ability of chemically resistant PTFE significantly degraded over 72 hours, while the permeable graphene film of the present invention provided excellent, anti-fouling, stable, long-term membrane performance over 144 hours of MD operation, making permeable graphene film a promising candidate which can enable single step, multi-stage free purification of harsh chemical or mine waste waters in low and high pHs.

Comparison of Membrane Performance of PVDF MD Membrane and Permeable Graphene-Based Membranes with PMMA Binders for Purification of Extreme pH Waters.

To demonstrate the wider applicability of permeable graphene in different supporting membrane, PMMA binder was used, due to its common utility as a binding agent for graphene wet-transfer. It is not necessary to remove the binder in this case, which enabled the utilization of other widely used but less chemically resistant PVDF MD membrane as supporting layer for the PMMA binder/nanochannel graphene. Utilization of binder in permeable graphene enable its wider integration into other types of polymeric base membranes.

MD testing was carried out on the comparative PVDF membrane and the composite PVDF/PMMA/nanochannel graphene membrane of the present invention using same mixture of extreme pH waters, (35 gL⁻¹ NaCl/0.1M H₂SO₄, pH2 and 35 gL⁻¹ NaCl/0.1M NaOH, pH13) over 72 hours. The water vapour flux, salt rejection and pH were continuously monitored over 72 hours of testing period. However, in the case of drastic membrane failure, experiment was stopped before the 72 hours.

Membrane test with acidic feed solution (35 gL⁻¹ NaCl/0.1M H₂SO₄, pH2), shows that the pristine PVDF MD membrane's performance degraded significantly over short period of operation time (10 hours). Membrane's structural integrity was lost after the 10 hours where the firm membrane turned soft and was not able to retain its shape. More importantly, its role as a rejection layer for solvated ions and removal of pH failed in short period of time. A rapid decrease in pH was observed, reaching pH of 3.5 at the end of 10 hours with decreasing in salt rejections to 61%. In this case, water vapour flux increased rapidly, from 23 Lm⁻²h⁻¹ to 140 Lm⁻²h⁻¹ over 10 hours revealing the sign of potential damage or surface property changes to the PVDF membrane as it came to contact with acidic feed solution. However, when permeable graphene film with PMMA binder was incorporated on the PVDF membrane, a stable neutral pH was obtained with an excellent stable salt rejection of 99.9% and stable average water flux of 20 Lm⁻²h⁻¹ (20.5 Lm⁻²h⁻¹ to 19.8 Lm⁻²h⁻¹) being observed for 72 hours of operation. This, again revealed the anti-fouling nature, excellent salt rejection capability and excellent H₃O⁺ rejection capabilities of permeable graphene film with binder. Compared to permeable graphene case without PMMA binder, a small drop in water vapour flux was observed from 25 Lm⁻²h⁻¹ to 20 Lm⁻²h⁻¹. Similarly, membranes were tested with basic feed solution (35 gL⁻¹ NaCl/0.1M NaOH, pH13). A pristine PVDF MD membrane exhibited significant performance degradation over short period of operation time (20 hours). A rapid increase in pH was again observed, reaching pH of 9.6 at the end of 20 hours with rapid decrease in salt rejection from 99.9 to 53%. Like the acidic feed solution case, water vapour flux rapidly increased from 23 Lm⁻²h⁻¹ to 72 Lm⁻²h⁻¹ over 20 hours. The PVDF membrane also showed signs of surface property changes as it lost its structural integrity and a heavy discoloration was observed. However, when permeable graphene film with PMMA binder was incorporated on the PTFE membrane, stable neutral pH was obtained with an excellent, stable salt rejection of 99.9% and stable average water flux of 21 Lm⁻²h⁻¹ (20.5 Lm⁻²h⁻¹ to 21 Lm⁻²h⁻¹) was observed for 72 hours of operation, again revealing anti-fouling nature, excellent salt rejection capability and excellent OH⁻ rejection capabilities of permeable graphene film with binder unlike pristine PVDF membrane case.

To investigate the underlying membrane's structural integrity, the graphene film was peeled from the supporting PVDF membrane. The base PVDF membrane had maintained its structural integrity and was mechanically stable after 72 hours of acidic and basic feed water filtration. More importantly, no discoloration in the base membrane was observed where the permeable graphene of the present invention acted as an excellent protective layer for less chemically resistant PVDF membrane. Overall, in the case of water mixtures with extreme pHs (pH2 and pH13) the permeable graphene film with binder acted as an excellent, anti-fouling, pH neutralising, long-term stable membrane in addition to protecting the base membrane of low chemical stability.

### Preserving the Properties of Supporting Membrane by Chemically Stable Permeable Graphene Film

To further investigate the role of permeable graphene as a protective layer for supporting membrane a series of contact angle measurements were undertaken to determine the changes in the membrane's surface properties. The MD process requires the membrane surface to be highly hydrophobic in order for effective water vapour passage, which is why PTFE and PVDF membrane are widely used for MD processes. The pristine PTFE membrane exhibit highly hydrophobic surface evident by the formation of a spherical droplet on membrane surface with high contact angle of 131°. However, after 72 hours of MD operation, there is a reduction in contact angle to 96° after testing with acidic feed solution and 107° after testing with basic feed solution, which is confirmed by a dome shape water droplet. However, when permeable nanochannel graphene is incorporated, the contact angle of the graphene remains unchanged after the test, as does the underlying PTFE membrane's surface properties which show a nice clear spherical water droplet with contact angle of 121°. To expose the underlying PTFE substrate, the graphene had to be carefully scratched off from the substrate. Full removal of graphene was not possible due to strong adhesion, which may explain subtle difference to its original surface properties. These experiments clearly demonstrate permeable graphene's chemical stability and role in preserving base membrane surface properties.

A similar effect has been observed in the case of PVDF membranes. A pristine PVDF membrane exhibits a highly hydrophobic surface with high contact angle of 141°. However, after testing with 10 and 20 hours with acidic and basic feed solutions, the contact angle of the PVDF membrane reduced dramatically, to 103° after testing with acidic feed water and 64° after testing with basic feed solution. This was confirmed by the presence of dome shape water droplets on membrane surface, rather than the original more spherical droplets. However, when permeable graphene with binder is incorporated, after test contact angle measurement shows, 139° after testing with acidic feed solution and 127° after testing with basic feed solution as well retaining the appearance of a spherical water droplet on the membrane surface. These results reinforce the role of permeable graphene with binder in preserving the surface properties of less chemically resistant PVDF membrane. Like the PTFE membrane case above, the surface properties of permeable graphene with a binder were also preserved before and after the tests with acidic and basic water mixtures. The chemically stable nature of graphene was demonstrated by performing Raman areal mapping ID/IG ratios on a permeable nanochannel graphene sample on PTFE. A similar ID/IG ratio values of 0.1 to 0.3 were observed both before and after testing, revealing the structural properties of the permeable graphene film of the present invention was stable after testing with either acidic or basic feed solution. Overall, these measurements show the importance role of a chemically stable, permeable graphene as excellent membrane in itself as well as its role in preserving the membrane surface properties of membranes with a less chemically stable nature.

Without wishing to be bound by theory, it is believed that effective rejection of solvated ions in feed water stream takes place at overlapping of grain boundaries of graphene layers which permit the passage of water but not solvated ions or larger species. The polycrystalline nature of our the present nanochannel graphene film means that there are numerous such grain boundaries present which leads to a useful flux of water molecules.

After-test SEM analysis of the graphene samples shows the graphene surface which was facing the acidic and basic solutions were covered with salt particles. However, the membrane surface which was facing the membrane side showed very clean graphene surface without any sign of salt on its surface which is reinforced by EDX mapping of sodium ions on the graphene surface. This demonstrated that solvated ion rejection must have taken place at the surface of the nanochannel graphene films. To further investigate the hypothesis that nanochannels arising from overlapping of grain boundaries the nanochannel graphene film formed an effective water passage and salt rejection layer, TEM analysis and EDX mapping were conducted at the regions with overlapping grain boundaries.

TEM analysis of after test samples showed numerous regions with overlapping of grain boundaries over large area of graphene film. In regions where there is an overlapping of grain boundaries, a strong accumulation of salt was observed along the grain boundaries and overlapping regions revealed by EDX mapping of sodium ions at the overlapping of grain boundaries, providing a strong experimental evidence for the hypothesis that these boundary overlaps or mismatches acted as a solvated ion rejection site as well as a water passage region. Traces of other metallic salts on the permeable nanochannel graphene surface were also observed after prolonged operation of the MD process in acidic and basic environment which are believed to arise from slow dissolution of metallic alloy heating elements used heat the feed solution.

### Stable, Anti-Fouling, Removal of pH by Permeable Graphene

The present inventors have also discovered other many important advantageous features of using multi-layer graphene with nanochannels as an effective anti-fouling membrane which is stable under harsh acidic and basic condition and can reject solvated salt ions and H₃O⁺ and OH⁻ ions. Although there are some filtration membranes which can withstand such harsh pH conditions, those membranes still suffer damages after prolonged exposures, can exhibit poor salt rejection and are unable to obtain neutral pH water in the permeate streams.

The present Applicants experiments showed that even chemically resistant PTFE MD membrane failed to neutralise pH from feed solutions of extremely acidic or basic solutions where prolonged operation lead eventual membrane performance degradation. To further investigate the ability of the graphene films of the present invention to neutralize pH at the permeate streams, X-ray diffraction spectroscopy (XRD) measurements were performed experimentally and molecular dynamic simulation was used to investigate the interaction between the solvated species in acidic and basic feed solution and the nanochannel graphene films of the present invention. XRD measurements of the permeable nanochannel graphene on PTFE membrane were carried out to determine the D-spacing of the graphene film before and after filtration. There was negligible change to D-spacing of the permeable nanochannel graphene film of the present invention which explains the excellent membrane stability of water permeation channels.

Molecular dynamics simulation (MDS) affirmed the presently proposed water transport mechanisms through the overlapping grains of graphene, the anti-fouling property and the rejection of hydrated ion species in acidic and basic environment of the permeable nanochannel graphene-based membrane.

### EXAMPLES

### Comparative Example 1—Non-Porous Graphene Film

This example is as described in the Applicant's co pending PCT/AU2016/050738 and sets out the “base” process for preparing simple high quality graphene films.

The growth of graphene was carried out in a thermal CVD furnace (OTF-1200X-UL, MTI Corp). A quartz tube was used. Polycrystalline Ni foils (25 μm, 99.5% or 99%, Alfa Aesar) were used as the growth substrate.

Two alumina crucibles were loaded into a quartz tube. One crucible contained the carbon source, which was 0.15-0.25 mL of soybean oil. The other crucible held a square (10 cm²) of the Ni foil growth substrate. These two crucibles were placed close proximity within the quartz tube. The tube was positioned so that both crucibles were within the heating zone of the furnace. The open ends of the quartz tube were then sealed.

The furnace temperature was raised to 800° C. (30° C./min) followed by maintaining the temperature for 15 mins for 99.5% purity Ni foil and 3 mins for 99% purity Ni foil at 800° C. to form a graphene lattice. Following lattice formation, the growth substrate was immediately removed from the heating zone to a cooling zone to enable cooling at a controlled rate (50-100° C./min) to allow segregation of the graphene lattice from the metal substrate to form a deposited graphene.

The pressure in the tube was maintained at ambient pressure. Throughout the entire growth process, no additional gases were introduced into the quartz tube.

Once cooled to ambient temperature, the substrate was removed from the tube and the as-grown graphene film was analysed using conventional techniques, as described below. The visible spectrum transmittance was 94.3%. In addition, Raman spectra indicate that graphene is formed with a relatively low proportion of defects and being very thin (three or less films). These characteristics suggest that this graphene obtain from this process is high quality.

A poly (methyl methacrylate) (PMMA)-assisted transfer of graphene was used. 46 mg/mL of PMMA (Mw 996,000) was spin-coated on the as-grown graphene on Ni foil (3000 rpm for 1 min). The sample was then dried in open air for 12 hours. Subsequently, the underlying Ni foil was dissolved in 1 M FeCl₃ in 30 minutes. The PMMA/graphene film then floated to the surface. This was washed several times with deionised water. Next, the PMMA/graphene was lifted off from the deionised water bath and transferred onto a glass substrate. The PMMA was then dissolved with acetone, and the sample was repeatedly washed with deionised water. The graphene isolated on glass was then used for subsequent microscopy and electrical characterizations. This method of transfer was applicable to all permeable graphene films produced according to the present invention.

### Comparative Example 2—Controlled Thickness Non-Porous Graphene

The growth of graphene was carried out as described for example 1, with modification to the amount of graphene and the cooling rate. A quartz tube was used. Polycrystalline Ni foils (25 μm, 99.5% or 99%,) were used as the growth substrate.

Two alumina crucibles were loaded into a quartz tube. One crucible contained the carbon source, the other crucible held the Ni foil growth substrate. These two crucibles were placed in close proximity inside the quartz tube. The tube was positioned so that both crucibles were within the heating zone of the furnace. The open ends of the quartz tube were then sealed.

The furnace temperature was raised to 800° C. (30° C./min) followed by maintaining the temperature for 15 mins to allow graphene lattice formation on 99.5% purity Ni foil and 3 mins for 99% purity Ni foil at 800° C.

After the growth step, the growth substrate was immediately removed from the heating zone to a cooling zone and cooled at the controlled rate.

The pressure in the tube was maintained at ambient pressure. Throughout the entire growth process, no additional gases were introduced into the quartz tube. Once cooled to ambient temperature, the substrate was removed from the tube and analysed.

### Inventive Example 3—Nanoporous Graphene

Single-step ambient-air growth of graphene film with nanometer size pores in graphene film

The growth of porous graphene film was carried out in a thermal CVD furnace (OTF-1200X-UL, MTI Corp) with a quartz tube. Polycrystalline Ni foils (25 μm, 99.5% or 99%, Alfa Aesar) were used as the growth substrate. Two alumina crucibles were loaded into a quartz tube, where one crucible holds the precursor, 0.15-0.16 mL of soybean oil, and the other holds the Ni foil growth substrate. These two crucibles were placed in the heating zone of the furnace and the openings of the quartz tube were sealed. Next, the furnace temperature was raised to 800° C. (30° C./min) followed by an annealing for 3 mins at 800° C. During the annealing stage, pressure in the tube was maintained at atmospheric pressure. After the annealing step, the growth substrate was immediately removed from the heating zone to enable a rapid cooling (25° C./min), right after sample was removed from the heating zone, all the air inside the quartz tube was removed from the chamber and sample was cooled in the cooling zone under vacuum. Throughout the entire growth process, no compressed gases were introduced into the quartz tube.

### Permeable Graphene Synthesis: Compressed Gas Free, Ambient Air CVD of Polycrystalline Nanochannel Graphene

The growth of nano-permeable graphene film was carried out in a thermal CVD furnace (OTF-1200X-UL, MTI Corp) with a quartz tube. Polycrystalline Ni foils (25 μm, 99%, Alfa Aesar) were used as the growth substrate. The experimental schematic is shown in FIG. 2. Two alumina crucibles were loaded into a quartz tube, where one crucible holds the precursor, 0.17 mL of soybean oil, and the other holds the Ni foil growth substrate. These two crucibles were placed in the heating zone of the furnace and the openings of the quartz tube were sealed. The growth of graphene proceeds with a gradual heating and fast quenching temperature profile. Firstly, the furnace temperature was raised to 800° C. (30° C./min) followed by an annealing for 3 mins at 800° C. During the annealing stage, pressure in the tube was maintained at atmospheric pressure. Throughout the heating stage (200 to 800° C.), atmospheric pressure was maintained in the quartz tube by allowing this build-up of gases to exit via the exhaust of the tube. A controlled gas environment was created in the tube through enabling the circulation of gases produced by precursor evaporation. Following the heating stage, pressure within the quartz tube was stabilized at atmospheric pressure. No additional gases were introduced into the quartz tube throughout the entire growth process. Such growth process resulted in formation of polycrystalline, few to multilayer graphene sheets with numerous grain boundaries.

After the annealing step, all the air inside the quartz tube was removed from the chamber and sample was cooled under vacuum with a delay time. After the delay time, the sample was rapidly cooled from a heating zone for the homogeneous and continuous graphene films to segregate. Due to the evaporation and thermal expansion of the precursor material, a small build-up in pressure within the tube was observed. However, cooling rate was controlled at slower cooling rate of (23-20° C./min). Slower cooling rate was generated by introducing the delay in the removal of the samples from the heating zone. Delay in removal of sample to the cooling zone generated the nanocrystalline domains, multi-layer graphene (2 to 10 layers) with mismatching graphene overlapping between the graphene sheets. Such mismatching overlaps create the nanopermeability in graphene. Throughout the entire growth process, no compressed gases were introduced into the quartz tube.

TEM micrographs show multi-layer graphene with many grain boundaries (nanocrystalline graphene) represented in (fine dark lines in TEM image) with many mismatching overlapping regions (more darker lines in TEM image) in the graphene films representing presence of permeable channels between the graphene layers.

For further TEM analysis to confirm the existence of nanochannels via formation of overlapping of graphene domain boundaries, via ambient air CVD process, a thinner graphene film (predominantly single to bi-layer) was synthesized by using the lower precursor amount of 0.155 ml while keeping the other protocols the same.

### Transfer of Graphene

A poly (methyl methacrylate) (PMMA)-assisted transfer of graphene was adopted. Briefly, 46 mg/mL of PMMA (Mw 996,000 Sigma Aldrich) was spin-coated onto the as-grown graphene on Ni foil (3000 rpm for 1 min). The sample was then dried in open air for 12 h or a block heater for 10 minutes at 80° C.

Subsequently, the underlying Ni foil was dissolved in 1 M FeCl₃ in 30-120 minutes as required. The PMMA/graphene film then floated to the surface. This was washed several times with deionized (DI) water. Next, the PMMA/graphene was lifted off from the DI water bath and transferred onto the membrane substrate. The PMMA was then dissolved with acetone, and the sample is rinsed with DI water.

For the preparation of PMMA binder/permeable graphene/PVDF membrane, PMMA/permeable graphene samples were lifted off from the DI water bath and transferred onto the PVDF membrane substrate and washed several times with DI water and dried before the usage. Similarly, for the preparation of permeable graphene on PTFE membrane, after the PMMA/permeable graphene was lifted off, it was transferred to PTFE membrane where PMMA was then dissolved with acetone. The samples were dried in open air before use. The sample was rinsed with DI water. Commercial PTFE membrane (Ningbo changqi PTFE membrane) was used for the preparation of permeable graphene/PTFE membrane. For the synthesis of PMMA binder/permeable graphene/PVDF membrane, PVDF membrane was fabricated using electrospinning methods.

### Microscopy and Microanalysis

Raman spectroscopy was performed using a Renishaw inVia spectrometer with Ar laser excitation at 514 nm and a probing spot size of about 1 μm2. Atomic force microscopy (AFM) images were acquired with an Asylum Research MFP-3D AFM operating in intermittent contact (“tapping”) mode with a Budget Sensors TAP150AI-G cantilever (fR=123 kHz, Q=1745 and k=2.1 Nm-1, with free-air amplitude=100 nm and feedback set-point=70%). Image analysis was performed using the Scanning Probe Image Processor (SPIP™) software produced by Image Metrology A/S. Energy filtered-Transmission electron microscopy (TEM) was performed using a JEOL 2200FS TEM microscope operated at 200 kV. Optical images were obtained with an Olympus BX51 optical microscope. Transmittance measurements were obtained using a Varian Cary 5000 UV-Vis spectrophotometer. A graphene area of 2 cm² was used, and optical spectra were recorded in the wavelength range from 300-400 nm to 800 nm.

### Membrane Distillation Setup

Direct contact membrane distillation (DCMD) was conducted using a closed-loop bench-scale membrane test apparatus (FIG. 20). The membrane cell was made of acrylic plastic to minimize heat loss to the surroundings. The flow channels were engraved in each of two acrylic blocks that made up the feed and permeate semi-cells. Each channel is 0.3 cm deep, 2 cm wide, and 2 cm long; and the total active membrane area was 4 cm². Temperatures of feed and distillate solutions were controlled by two heater/chillers (Polyscience, IL, USA), and were continuously recorded by temperature sensors that were inserted at the inlet and outlet of the membrane cell. Both feed and distillate streams were concurrently circulated by two gear pumps. The same crossflow rate of 30 L h⁻¹ (corresponding to the crossflow velocity of 9 cm s⁻¹) was applied to both feed and distillate simultaneously in order to minimize the pressure difference across the MD membrane. Weight change of the distillate tank was recorded by an electronic balance (Mettler Toledo, Ohio, USA) with a data logger. All piping used in the DCMD test unit was covered with insulation foam to minimize heat loss.

### Experimental Protocol for Membrane Distillation of Saline Water

MD fouling experiments were conducted using four types of saline water and saline water with contaminant mixtures: 70 g L⁻¹ NaCl solution, 70 g L⁻¹ NaCl solution with 1 mM sodium dodecyl sulfate (SDS), 70 g L⁻¹ NaCl solution with 1 g L⁻¹ mineral oil and 1 mM NaHCO₃ (the oil emulsion was prepared by vigorous mixing using Modular Homogenizers at speed of 20,000 rpm for 30 min), and real seawater, respectively. The comparison between the mineral oil and light crude oil was tabulated in Table S2, Supplementary Information.

Feed and distillate volumes of four and one litre were used, respectively. Temperate of inlet feed solution is 60° C.; while that of the distillate inlet stream is 20° C. in all experiments. A new membrane sample was used for each experiment. Water vapour flux was recorded by a digital balance continuously. Conductivity of the distillate was measured by a conductivity meter (HQ14d, Hach, CO) every 5 minutes. All feed solutions were processed by DCMD for 72 hours, except for the cases of mineral oil tests which was performed for 48 hours and the case where long term stability is demonstrated with real sea water feed which was performed for 120 hours. Total organic carbon (TOC) was analysed using a TOC/TN analyzer (TOC-VCSH, Shimadzu, Kyoto). Membrane surface charge was measured by a SurPASS electrokinetic analyzer (Anton Paar CmbH, Graz, Austria). Zeta potential of the membrane surface was calculated from the measured streaming potential using the Fairbrother-Maastin approach. All streaming potential measurements were performed in a background electrolyte solution (i.e. 10 mM KCl). The background solution was also used to completely flush the cell before pH titration using either hydrochloric acid (0.5 M) or potassium hydroxide (0.5 M). Surface energy of the membranes were calculated by measuring the contact angle using three different liquids (two polar and one non-polar) of well-known surface tension, employing the Lifshitz van der Walls (non-polar) and Lewis acid-base (polar) approaches.³⁶ Commercial PVDF MD membrane (Durapore, 0.45 μm pore size, 280 μm thickness) experiments were carried out in same experimental protocol as PTFE membrane case.

### Experimental Protocol for Membrane Distillation of Acidic and Basic Waters

Experiments were conducted using 2 types of water with high (pH 13) and low (pH 2) pH with addition of saline water mixtures. Acidic solution (pH 2) was prepared by adding 1M sulfuric acid to 35 g L⁻¹ NaCl solution to reach the pH2. Similarly, basic solution (pH 13) was prepared by adding 1M NaOH solution into 35 g L⁻¹ NaCl solution.

Feed and distillate volumes of four and one litre were used, respectively. The temperature of inlet feed solution was 40° C. while that of the distillate inlet stream was 20° C. in all experiments. Water vapour flux was recorded by a digital balance continuously. Conductivity of the distillate was measured by a conductivity meter (HQ14d, Hach, CO) every 5 minutes. All feed solutions were processed by DCMD for 72 hours except for the pristine PVDF membrane where conductivity and flux significantly increased. Fresh samples were used for all the experiments except for the test of permeable graphene/PTFE membrane, where 72 hours of testing under acidic water mixtures took place first. After the test, the sample was cleaned several times with DI water before testing under basic water mixtures for 72 hours.

### CONCLUSION

Thus, it can be seen that the present provides a high quality nanoporous or nanochannel graphene having multiple pores and channels capable of acting as a membrane or filter, as well as having advantages such as the ability to use a renewable low quality biomass, air at atmospheric pressure and lower temperatures and without the need for post treatment process to form pores.

The present invention allows for the synthesis of high quality graphene films to take place in an ambient-air environment via thermal chemical vapour deposition. The absence of a vacuum chamber means that the present process can be highly scalable. Ambient-air synthesis according to the present invention facilitates a streamlined integration into the large-scale graphene production infrastructure such as roll-to-roll or batch processing required for industrial production.

The present invention allows for thermal-based synthesis in the absence of any purified compressed feedstock gases (e.g., methane, hydrogen, argon, nitrogen, etc.), which are costly and/or highly explosive. The synthesis technique of the present invention does not require any purified feedstock gases, and instead, can utilize far cheaper carbon source material such as a renewable biomass as the precursor for the synthesis of graphene films. Notably, this enables the process of the present invention to be technologically sustainable, and also significantly cheaper and safer than presently available methods.

The present methods are thus safe, environmentally-friendly, and resource-efficient technique for graphene synthesis.

### REFERENCES

1. Bunch J S, et al. Impermeable Atomic Membranes from Graphene Sheets. Nano Letters 8, 2458-2462 (2008).
2. Surwade S P, et al. Water desalination using nanoporous single-layer graphene. Nature

Nanotechnology 10, 459-464 (2015).
3. Garaj S, Hubbard W, Reina A, Kong J, Branton D, Golovchenko J A. Graphene as a subnanometre trans-electrode membrane. Nature 467, 190-193 (2010).
4. Abraham J, et al. Tunable sieving of ions using graphene oxide membranes. Nature Nanotechnology 12, 546-550 (2017).
5. Sun P, Wang K, Zhu H. Recent Developments in Graphene-Based Membranes: Structure, Mass-Transport Mechanism and Potential Applications. Advanced Materials 28, 2287-2310 (2016).
6. Seo D H, et al. Single-step ambient-air synthesis of graphene from renewable precursors as electrochemical genosensor. Nature Communications 8, 14217 (2017).
7. Drioli E, Ali A, Macedonio F. Membrane distillation: Recent developments and perspectives. Desalination 356, 56-84 (2015).
8. Curcio E, Drioli E. Membrane Distillation and Related Operations—A Review. Separation & Purification Reviews 34, 35-86 (2005).
9. Tijing L D, Woo Y C, Choi J-S, Lee S, Kim S-H, Shon H K. Fouling and its control in membrane distillation—A review. Journal of Membrane Science 475, 215-244 (2015).
10. Dudchenko A V, Chen C, Cardenas A, Rolf J, Jassby D. Frequency-dependent stability of CNT Joule heaters in ionizable media and desalination processes. Nat Nano 12, 557-563 (2017).
11. Lee J, Boo C, Ryu W H, Taylor A D, Elimelech M. Development of Omniphobic Desalination Membranes Using a Charged Electrospun Nanofiber Scaffold. ACS Appl Mater Interfaces 8, 11154-11161 (2016).
12. Lu X, Peng Y, Ge L, Lin R, Zhu Z, Liu S. Amphiphobic PVDF composite membranes for anti-fouling direct contact membrane distillation. Journal of Membrane Science 505, 61-69 (2016).
13. Camacho L, et al. Advances in Membrane Distillation for Water Desalination and Purification Applications. Water 5, 94 (2013).
14. Lin S, Nejati S, Boo C, Hu Y, Osuji C O, Elimelech M. Omniphobic Membrane for Robust Membrane

Distillation. Environmental Science & Technology Letters 1, 443-447 (2014).
15. Boo C, Lee J, Elimelech M. Omniphobic Polyvinylidene Fluoride (PVDF) Membrane for Desalination of Shale Gas Produced Water by Membrane Distillation. Environmental Science & Technology 50, 12275-12282 (2016).
16. Pop E, Varshney V, Roy A K. Thermal properties of graphene: Fundamentals and applications. MRS

Bulletin 37, 1273-1281 (2012).
17. Jung H, et al. High Through-Plane Thermal Conduction of Graphene Nanoflake Filled Polymer Composites Melt-Processed in an L-Shape Kinked Tube. ACS Applied Materials & Interfaces 7, 15256-15262 (2015).
18. Woo Y C, et al. Graphene/PVDF flat-sheet membrane for the treatment of R O brine from coal seam gas produced water by air gap membrane distillation. Journal of Membrane Science 513, 74-84 (2016).
19. Ruan G, Sun Z, Peng Z, Tour J M. Growth of Graphene from Food, Insects, and Waste. ACS Nano 5, 7601-7607 (2011).
20. Sun Z, Yan Z, Yao J, Beitler E, Zhu Y, Tour J M. Growth of graphene from solid carbon sources. Nature 468, 549-552 (2010).
21. O'Hern S C, et al. Selective Ionic Transport through Tunable Subnanometer Pores in Single-Layer Graphene Membranes. Nano Letters 14, 1234-1241 (2014).
22. Rollings R C, Kuan A T, Golovchenko J A. Ion selectivity of graphene nanopores. Nature Communications 7, 11408 (2016).
23. Jain T, et al. Heterogeneous sub-continuum ionic transport in statistically isolated graphene nanopores. Nature Nanotechnology 10, 1053-1057 (2015).
24. Dong J, Wang H, Peng H, Liu Z, Zhang K, Ding F. Formation mechanism of overlapping grain boundaries in graphene chemical vapor deposition growth. Chemical Science 8, 2209-2214 (2017).
25. Garlow J A, Barrett L K, Wu L, Kisslinger K, Zhu Y, Pulecio J F. Large-Area Growth of Turbostratic Graphene on Ni(111) via Physical Vapor Deposition. Scientific Reports 6, 19804 (2016).
26. Niyogi S, et al. Spectroscopy of covalently functionalized graphene. Nano Letters 10, 4061 (2011).
27. Lin S, Nejati S, Boo C, Hu Y, Osuji C O, Elimelech M. Omniphobic Membrane for Robust Membrane Distillation. Environ Sci Technol Lett 1, 443-447 (2014).
28. Oschmann N, Nghiem L D, Schafer A I. Fouling mechanisms of submerged ultrafiltration membranes in greywater recycling. Desalination 179, 215-223 (2005).
29. Liu Y, Yakobson B I. Cones, Pringles, and Grain Boundary Landscapes in Graphene Topology. Nano Letters 10, 2178-2183 (2010).
30. Nair R R, Wu H A, Jayaram P N, Grigorieva I V, Geim A K. Unimpeded Permeation of Water Through Helium-Leak-Tight Graphene-Based Membranes. Science 335, 442-444 (2012).
31. Kim K, Lee Z, Regan W, Kisielowski C, Crommie M F, Zettl A. Grain Boundary Mapping in Polycrystalline Graphene. ACS Nano 5, 2142-2146 (2011).
32. Alkhudhiri A, Darwish N, Hilal N. Membrane distillation: A comprehensive review. Desalination 287, 2-18 (2012).
33. Harb M, et al. The c-axis thermal conductivity of graphite film of nanometer thickness measured by time resolved X-ray diffraction. Applied Physics Letters 101, 233108 (2012).
34. Fugallo G, Cepellotti A, Paulatto L, Lazzeri M, Marzari N, Mauri F. Thermal Conductivity of Graphene and Graphite: Collective Excitations and Mean Free Paths. Nano Letters 14, 6109-6114 (2014).
35. Maphutha S, Moothi K, Meyyappan M, Iyuke S E. A carbon nanotube-infused polysulfone membrane with polyvinyl alcohol layer for treating oil-containing waste water. Scientific Reports 3, 1509 (2013).
36. Perdew J P, Burke K, Ernzerhof M. Generalized Gradient Approximation Made Simple. Physical Review Letters 77, 3865-3868 (1996).

1. A continuous permeable graphene film comprising 2 or more layers of graphene and nanochannels or nanopores providing a fluid passage from one face of the permeable graphene film to the other, said nanochannels or nanopores providing a fluid passage from one face of the permeable graphene film to the other.

2. A continuous permeable graphene film according to claim 1 comprising 2 or more layers of graphene forming nanochannels wherein each nanochannel being comprised of a fluidly connected series of gaps between edge mismatches of adjacent graphene grains within said 2 or more layer adjacent sheets, said nanochannels providing a fluid passage from one face of the permeable graphene film to the other.

3. A continuous permeable graphene film according to claim 1 or claim 2 comprising 2-10 layers.

4. A continuous permeable graphene film according to claim 2 or claim 3 wherein the gaps are located at the junction of grain boundaries in the graphene film.

5. A permeable membrane comprising a permeable support membrane overlaid by a continuous permeable graphene film according to any one of the preceding claims.

6. A permeable membrane according to claim 5 further including a binder.

7. A permeable membrane according to any one of the preceding claims wherein the continuous permeable graphene film has a thickness of 0.7 to 3.7 nm.

8. A permeable membrane according to any one of the preceding claims wherein the continuous permeable graphene film has functional pore size in the range of 0.34-3.0 nm.

9. A permeable membrane according to any one of the preceding claims wherein the membrane is a two component membrane wherein the permeable support membrane and the graphene film are adjacent to each other or attached to each other.

10. A permeable membrane according any one of the preceding claims comprising a permeable support membrane sandwiched between two continuous permeable graphene films, each continuous permeable graphene film having a plurality of nanochannels or nanopores extending therethrough.

11. A permeable membrane according to any one of the preceding claims wherein the permeable support membrane is a porous polymeric membrane.

12. A permeable membrane according to any one of the preceding claims wherein the permeable support membrane is a commercial porous polymeric MD (Membrane Distillation) membrane.

13. A method of preparing a deposited permeable continuous nanochannel graphene film comprising the steps of heating a metal substrate and an excess of carbon source in a sealed ambient environment to a temperature which produces carbon containing vapour from the carbon source such that the vapour comes into contact with the metal substrate, maintaining the temperature for a time sufficient to form a graphene lattice, cooling the sample at a retarded cooling rate under reduced pressure for a delay time, and then flash cooling the substrate under reduced pressure form a deposited permeable nanochannel graphene.

14. The method according to claim 13 wherein the ambient environment is air at atmospheric pressure or a vacuum.

15. The method according to claim 13 or 14 wherein the metal substrate is a transition metal substrate.

16. The method according to any one of claims 13 to 15 wherein the metal substrate is nickel or copper.

17. The method according to claim 16 wherein the metal substrate is nickel and the ambient environment is air at atmospheric pressure.

18. The method according to claim 16 wherein the metal substrate is copper and the ambient environment is an evacuated chamber prior to sealing and heating.

19. The method according to any one of claims 13 to 18 wherein the carbon source is biomass or is derived from biomass.

20. The method according to any one of claims 13 to 19 wherein the method is free from feedstock gases.

21. The method according to any one of claims 13 to 20 wherein the step of heating employs a carbon rich environment.

22. The method according to any one of claims 13 to 21 wherein the metal substrate and carbon source are heated to a temperature sufficient to form a graphene lattice in the range 650° C.−900° C.

23. The method according to any one of claims 13 to 22 wherein the retarded cooling rate takes place at a rate of from 5° C. to 10° C./minute.

24. The method according to any one of any one of claims 13 to 23 wherein flash cooling takes place at a rate of 25° C./minute-100° C./minute.

25. A method of preparing a deposited permeable continuous nanochannel graphene film on a support membrane comprising preparing deposited permeable continuous nanochannel graphene film on a substrate according to any one of claims 13 to 24, decoupling the film from the substrate to provide a free permeable continuous nanochannel graphene film and applying the free permeable continuous nanochannel graphene film to the support membrane.

26. The method according to claim 25 wherein the deposited permeable continuous nanochannel graphene film is decoupled from the underlying metal substrate by dissolving the substrate in an acidic environment to produce a free permeable continuous nanochannel graphene film.

27. The method according to claim 23 or 24 including the step of utilising a binder attached to the free permeable continuous nanochannel graphene film.

28. The method according to claim 27 wherein the binder attached to the free permeable continuous nanochannel graphene film is applied to the support membrane.

29. The method according to claim 28 wherein the binder is removed after the graphene film is applied to the support membrane.

30. The method according to claim 29 wherein the binder is removed by dissolution.

31. The method according to any one of claims 27 to 29 wherein binder is PMMA and the process proceeds via an intermediate PMMA bound permeable continuous nanochannel graphene film and the PMMA layer may be removed, for example, by dissolution, or it may be retained in the final product.

32. A method of purifying a feed water contaminated with a contaminant comprising providing said feed water to a permeable membrane according any one of claims 5 to 12 such that the feed water contacts the continuous permeable graphene film as a feed side, allowing water to pass through the permeable membrane to a filtrate side to provide a filtrate, and whereby the contaminant is retained on the feed water side.

33. A method according to claim 32 wherein the feed water is industrial waste water or water for desalination.

34. A method according to claim 32 or 33 wherein the industrial waste water is from mining, agriculture or material processing.

35. A method according to any one of claims 32 to 34 wherein the contaminant is a surfactant, oil or petroleum or residues of a surfactant, oil or petroleum product.

36. A method according to any one of claims 32 to 35 wherein the permeable graphene side of the membrane remains charge neutral over a wide range of pH's such as from pH2 to pH 13.

37. A method according to any one of claims 32 to 36 wherein the permeable graphene side of the membrane is antifouling

38. A method according to any one of claims 33 to 37 wherein the contaminant is a hydrated or solvated ion.

39. A method according to claim 38 wherein the hydrated or solvated ion has a radius larger than 0.9 nm³.

40. A method according to claim 32 wherein the feed water is water for desalination containing inorganic and organic species

41. A method according to claim 40 wherein the inorganic species include Na⁺ and Cl⁻.

42. A method according to any one of claims 32 to 41 wherein the feed water is sea water

43. A method according to any one of claims 32 to 42 wherein the feed water is acidic or basic outside physiological pH range.
